(19) United States
(12) Patent Application Publication
(10) Pub. No.: US 2024/0329285 A1
(43) Pub. Date: Oct. 3, 2024

(54) METHOD AND APPARATUS FOR PRODUCING AT LEAST ONE HOLLOW STRUCTURE, MIRROR, EUV LITHOGRAPHY SYSTEM, FLUID FEED APPARATUS AND METHOD FOR FEEDING A FLUID

(71) Applicant: Carl Zeiss SMT GmbH, Oberkochen (DE)

(72) Inventors: Tobias ULLSPERGER, Erfurt (DE); Stefan NOLTE, Jena (DE); Cristian GLEASON, Stuttgart (DE); Soeren KNORR, Aalen (DE); Thomas MONZ, Schlierbach (DE); Stefan XALTER, Oberkochen (DE); Michael KLASNA, Bad Aibling (DE); Christoph ZACZEK, Heubach (DE)

(21) Appl. No.: 18/741,925

(22) Filed: Jun. 13, 2024

Related U.S. Application Data
(63) Continuation of application No. PCT/EP2022/085520, filed on Dec. 13, 2022.

(30) Foreign Application Priority Data
Dec. 14, 2021 (DE) 10 2021 214 310.5
Dec. 14, 2021 (DE) 10 2021 214 318.0
Apr. 8, 2022 (DE) 10 2022 203 593.3

(51) Int. Cl. G02B 5/08; B23K 26/55; B23K 101/14; G03F 7/00

(52) U.S. Cl. CPC G02B 5/0891; B23K 26/55; G03F 7/702; G03F 7/70891; B23K 2101/14

(57) ABSTRACT

A hollow structure (28) is produced in a workpiece (25) to form a substrate for a mirror through material-removing processing with pulsed laser radiation (35). The pulsed laser radiation is focused into a focal region (39), forming a removal front (46) for the areal removal of material of the workpiece (25) by moving the focal region (39) along a movement pattern (41), and producing the hollow structure (28) by moving the removal front (46) within the workpiece (25). The removal front is not aligned perpendicular to an incoming radiation direction (Z) of the pulsed laser radiation (35) at the radiation entrance side (27) of the workpiece at least intermittently during the production. The hollow structure is produced in the form of a channel through which a fluid is able to flow.

### CROSS-REFERENCE TO RELATED APPLICATION

This is a Continuation of International Application PCT/EP2022/085520, which has an international filing date of Dec. 13, 2022, and the disclosure of which is incorporated in its entirety into the present Continuation by reference. This Continuation also claims foreign priority under 35 U.S.C. § 119 (a)-(d) to and also incorporates by reference, in its entirety, German Patent Applications DE 10 2021 214 310.5 filed on Dec. 14, 2021, DE 10 2021 214 318.0 filed on Dec. 14, 2021, and DE 10 2022 203 593.3 filed on Apr. 8, 2022.

### FIELD OF THE INVENTION

The invention relates to a method for producing at least one hollow structure in a workpiece preferably in the form of a substrate for a mirror, in particular for a mirror configured for reflecting extreme ultraviolet (EUV) radiation, through material-removing processing with pulsed laser radiation, comprising: radiating the pulsed laser radiation into the workpiece which is formed from a material transparent to the pulsed laser radiation from a radiation entrance side, focusing the pulsed laser radiation into a focal region, forming a removal front for the areal removal of material of the workpiece by moving the focal region along a movement pattern, and producing the hollow structure by moving the removal front within the workpiece. The invention also relates to a method for producing a hollow structure in the form of a channel in a workpiece, preferably in the form of a substrate for a mirror, in particular for an EUV mirror. The invention also relates to a mirror, in particular an EUV mirror, and to an EUV lithography system having at least one such EUV mirror.

### BACKGROUND

The invention moreover relates to an apparatus for producing at least one hollow structure, in particular at least one channel, in a workpiece, preferably in the form of a substrate for a mirror, in particular for an EUV mirror, comprising: a laser source for producing pulsed laser radiation, a holder for receiving the workpiece, a focusing device for focusing the laser radiation into a focal region, and a scanner optical unit designed to radiate the pulsed laser radiation onto a radiation entrance side of the workpiece received by the holder and to move the focal region.

The invention also relates to a fluid feed apparatus for feeding a fluid to at least one removal front when removing material by laser ablation, in particular by multi-photon laser ablation, from a workpiece, preferably from an in particular monolithic substrate for an EUV mirror. The invention also relates to a method for feeding a fluid to at least one removal front.

For the purposes of this application, an EUV lithography system is understood to mean an optical system that can be used in the field of EUV lithography. In addition to a projection exposure apparatus for EUV lithography which serves for production of semiconductor components, the lithography system may, for example, be an inspection system for inspection of a photomask used in such a projection exposure apparatus, also referred to hereinafter as reticle, for inspection of a semiconductor substrate to be structured, also referred to hereinafter as a wafer, or a metrology system which is used for measurement of a projection exposure apparatus for EUV lithography or parts thereof, for example for measurement of a projection optical unit.

In order to attain the smallest possible structure width for the semiconductor components to be produced, state-of-the-art projection exposure apparatuses, also known as EUV lithography apparatuses, are designed for an operating wavelength in the extreme ultraviolet wavelength range, also referred to as EUV wavelength range, that is to say in a range from approx. 5 nm to approx. 30 nm. On account of the short wavelength radiation, coated mirrors, which are also known as EUV mirrors, are used for beam guidance and focusing, the said mirrors comprising a substrate made of a material with a very low coefficient of thermal expansion. By way of example, the substrate material can be titanium-doped fused silica with a very low coefficient of thermal expansion. The productivity when producing the exposed wafers depends significantly on the power of the EUV light source used to produce the EUV radiation. However, a high power of the radiation incident on the EUV mirrors leads to an increased thermal load on the said EUV mirrors. Despite the extremely small coefficient of thermal expansion, the heat output introduced into the substrate leads to shape deviations of the highly precise mirror surfaces. Active cooling of the EUV mirrors may be provided to meet the demands of increased productivity and the resultant ever more powerful EUV light sources.

An efficient method is provided by volumetric cooling in the form of internal channels through which a liquid, water for example, flows in order to bring about cooling of the substrate; this is why these channels are also referred to as cooling channels below. A channel through which a liquid is able to flow forms an elongate cavity that is closed off in the circumferential direction, the cavity having no branching points and extending between a first end of the channel and a second end of the channel. At one or both ends, the channel may merge into further hollow structures located in the volume of the substrate. It is also possible for one or both ends of the channel to open up on the outer side of the substrate. A challenge in this context lies in the realization of hollow structures in the form of cooling channels within the volume of the substrate, the said cooling channels having a comparatively large diameter of more than approx. 1 mm as a rule and extending at a small distance of typically no more than approx. 10 mm below the surface of the substrate to which the reflective coating for reflecting the EUV radiation is applied.

To feed and remove the cooling liquid, it is typically necessary to equip the cooling channel, which is aligned substantially parallel to the surface of the mirror irradiated with EUV radiation, with angled flow and return channels which may be connected to the back side of the substrate, for example.

One approach for producing hollow structures consists in material processing using laser radiation. In this case, the workpiece material is damaged by appropriately high pulse intensities. Conventional glasses such as fused silica, borosilicate glass or else titanium-doped fused silica are transparent to laser radiation with wavelengths in the visible to the near infrared range.

### SUMMARY

It is an object of the invention to provide a method and an apparatus which enable the production of hollow structures with a complex geometry, in particular a curved and/or angled geometry, in a workpiece, preferably in a substrate for a mirror, in particular for an EUV mirror. It is a further object of the invention to provide a mirror, in particular an EUV mirror, and an EUV lithography apparatus having such a hollow structure. It is a further object of the invention to provide a mirror, in particular an EUV mirror, in which flow-induced vibrations arising when a fluid flows through the hollow structure are reduced. A further object of the invention lies in the provision of a fluid feed apparatus and a method which enable a fluid feed to at least one removal front, even when producing complex hollow structures.

### Subject Matter of the Invention

In a first aspect of the invention, this object is achieved by a method of the type set forth at the outset, in which a removal front that is not aligned perpendicular to an incoming radiation direction of the pulsed laser radiation at a radiation entrance side of the workpiece is formed at least intermittently in order to produce the hollow structure, with the hollow structure preferably being produced in the form of a channel through which a fluid, in particular a cooling fluid, is able to flow. The fluid can be a temperature control medium used to heat or cool. As a rule, the fluid will be a liquid, but it could also be a gas.

In the present application, the term “ablation front” is used synonymously with the term “removal front”. Material of the workpiece is removed at the removal front. The removal front forms an interface between the material of the workpiece and the already formed portion of the hollow structure. The lateral surface of the already formed portion of the hollow structure is adjacent to the removal front, more precisely an edge contour of the removal front.

The inventors have recognized that the production of hollow structures with undercuts, for example with a curved or angled geometry, benefits from the removal front at least intermittently not being aligned perpendicular to the incoming radiation direction of the pulsed laser radiation at the radiation entrance side of the workpiece, but the removal front rather being tilted and being aligned at an angle that differs from 90°, that is to say at an angle between 0° and 89°, with respect to the incoming radiation direction.

As a rule, the tilted removal front extends in a plane that is tilted with respect to the incoming radiation direction; however, in principle it is also possible for the removal front not to be planar and for it to deviate from a plane geometry. In this case, the angle at which the removal front is aligned with respect to the incoming radiation direction of the pulsed laser radiation is understood to be the angle with respect to an equivalent plane of the removal front. The equivalent plane is the plane that has the smallest possible distance from all points of the removal front. The equivalent plane is determined by the conventional ordinary least squares (OLS) method. In particular, the removal front may only have minor deviations from a planar or plane geometry and may approximate the plane geometry, for example in the form of small, stepped sections.

The incoming radiation direction is understood to mean the direction in which the pulsed laser radiation is incident on the radiation entrance side. The pulsed laser radiation focused on a respective focal position is typically a laser beam whose direction of propagation corresponds to the incoming radiation direction. Should the pulsed laser radiation not be radiated onto the radiation entrance side of the workpiece in perpendicular fashion, the direction of propagation of the pulsed laser radiation in the material of the workpiece differs from the incoming radiation direction at the workpiece on account of refraction.

The incoming radiation direction of the pulsed laser radiation onto the radiation entrance side of the workpiece is generally constant when forming the removal front. Should the incoming radiation direction of the pulsed laser radiation vary during the formation of the removal front, the incoming radiation direction is understood to mean the arithmetic mean of the incoming radiation directions at the radiation entrance side at all focal positions along the trajectories of the movement pattern.

As a rule, the thickness direction of the workpiece runs substantially parallel to the incoming radiation direction of the pulsed laser radiation at the workpiece. The thickness direction corresponds to the normal direction of the radiation entrance side at the position where the pulsed laser radiation passes through the radiation entrance side. The radiation entrance side through which the pulsed laser radiation enters the workpiece may be an approximately planar surface, which is aligned substantially perpendicular to the incoming radiation direction. However, it is also possible that the radiation entrance side forms a curved surface, for example a spherically curved surface, an aspherically curved surface or a free-form surface. To form a curved mirror surface, however, the for example planar radiation entrance side may be processed mechanically or in any other way even after the hollow structure or the hollow structures have been produced. It is also possible for the pulsed laser radiation to be incident on the radiation entrance side in non-perpendicular fashion.

Should the intention be to form a hollow structure with an undercut, the removal front may be aligned at an angle that differs from 90°, that is to say at an angle between 0° and 89°, with respect to the incoming radiation direction, at least during the production of the undercut. By way of example, such an alignment is advantageous if the intention is to form a section of the hollow structure whose longitudinal axis runs substantially parallel to the radiation entrance side. Naturally, the removal front may also be aligned at an angle with respect to the incoming radiation direction which differs from 90°, which is constant or which optionally varies depending on the position of the removal front within the workpiece during the production of the entire hollow structure. The angle of the removal front should be varied continuously and slowly, that is to say the difference angle between two directly successively formed removal fronts should be small.

The removal of material of the workpiece is typically caused by multi-photon absorption of the radiated-in laser radiation, which is why the removal process is also referred to as multi-photon laser ablation. The multi-photon absorption can take place in the material of the workpiece and/or in a fluid, typically a liquid, which is brought into contact with the removal front during the removal of material, as described in more detail below. Other chemical and/or physical processes may also bring about material removal. The parameters of the radiated-in laser radiation may be adapted to the respective process or optimized for the respective process which should bring about the material removal.

The hollow structure is preferably produced in the form of a curved channel through which a fluid, in particular a cooling fluid, is able to flow. As has been described further above, hollow structures provided in particular with undercuts, for example hollow structures in the form of curved channels, through which a fluid is able to flow may be produced by the method that has been described further above.

In a variant, the first emergence of the pulsed laser radiation from the material of the workpiece is in the region of the removal front. In this variant, the pulsed laser radiation propagates within the material of the workpiece between the radiation entrance side of the workpiece and the removal front, that is to say there is no cavity between the radiation entrance side and the removal front.

In a development of this variant, the pulsed laser radiation re-enters the material of the workpiece following the emergence from the material of the workpiece. This is typically the case should the intention be to form a section of the hollow structure that does not extend parallel to the incoming radiation direction. In this case, material of the workpiece, on which a portion of the pulsed laser radiation that was not completely absorbed by the material of the workpiece in the respective focal region is incident, is present at a side of the removal front distant from the radiation entrance face in the incoming radiation direction of the pulsed laser radiation.

In a further variant, the removal front within the workpiece is at least intermittently moved in a direction to the radiation entrance side of the workpiece. The movement of the removal front in the direction to the radiation entrance side of the workpiece can be parallel to the incoming radiation direction if a section of the hollow structure that extends parallel to the incoming radiation direction is formed. However, it is also possible for the movement of the removal front in the direction to the radiation entrance side to be superposed with a movement in the direction perpendicular thereto, for example when an angled or curved section of the hollow structure is formed.

In a further variant, when moving the removal front within the workpiece, material of the workpiece is at least intermittently adjacent to a side of an edge of the removal front that is distant from the radiation entrance side of the workpiece, the said side being distant from the radiation entrance side of the workpiece. As described further above, this is typically the case should the intention be to form a section of the hollow structure that does not extend parallel to the incoming radiation direction.

In a further variant, the removal front is moved starting from a side of the workpiece that is opposite to the radiation entrance side. The side of the workpiece that is opposite to the radiation entrance side and from which the removal front starts may be the back side of the workpiece, which is generally aligned substantially parallel to the beam entrance side. However, the side of the workpiece from which the removal front starts may also be a surface situated within the volume of the workpiece. By way of example, this may be the case if a hollow structure is already present in the workpiece and the hollow structure produced by the method starts from the already produced hollow structure. The hollow structure which is already present in the volume of the workpiece may have been produced using the method described herein; however, it is also possible as a matter of principle that this hollow structure was produced using a different material-removing method, for example using a mechanically abrasive method.

In a variant, a removal front aligned at an angle of between 0° and 89°, preferably between 0° and 80°, particularly preferably between 20° and 70°, in particular between 30° and 60° with respect to the incoming radiation direction is formed at least intermittently. As described further above, such an alignment of the removal front prevents or reduces the introduction of material modifications into a volume region of the workpiece situated below the removal front and therefore significantly reduces the stress introduced into the workpiece material when producing the hollow structure.

In a further variant, the focal region is moved along mutually offset trajectories of the movement pattern. In the method described here, the trajectories of the movement pattern are preferably aligned parallel to one another and extend in a straight line. By way of example, the distance between adjacent trajectories can be between approx. 0.01 mm and 0.5 mm. However, such an alignment is not mandatory, that is to say the trajectories of the movement pattern may also optionally be aligned in the form of concentric contours, for example in the form of concentric circles, or in any other way. The cross-sectional geometry of the movement pattern or the projection thereof into a plane perpendicular to the movement direction of the removal front corresponds to the cross-sectional geometry of the hollow structure. As a matter of principle, the cross-sectional geometry of the hollow structure is as desired and may be, for example, circular, elliptical, polygonal, etc. Modifying the spatial extent of the movement pattern depending on the position of the removal front within the workpiece also allows the diameter of the cross section of the hollow structure to be modified within certain boundaries when the removal front moves.

In a variant, for forming the removal front that is not aligned perpendicular to the incoming radiation direction, the trajectories of the movement pattern are offset from one another in or along the incoming radiation direction by virtue of the focal region being offset in the positive or negative incoming radiation direction or along the incoming radiation direction. In this variant, the trajectories of the movement pattern typically extend in a straight line and are aligned parallel to one another. In the case of the variant described here, the individual trajectories of the movement pattern are offset from one another along the incoming radiation direction in order to generate a removal front that is oblique with respect to the incoming radiation direction. A movement in a direction, for example in the Z-direction, is understood to mean a movement along or parallel to the respective direction, with the sign of the direction (+Z, −Z) not being taken into account.

In the simplest case of this variant, the focal range is offset by a constant absolute value in the incoming radiation direction for each further, adjacent trajectory starting from a trajectory at a lateral edge of the movement pattern. By way of example, a dynamic zoom lens can be used to offset the focal range in the incoming radiation direction.

In this variant, the tilted removal front is formed by a fast scanning of the movement pattern in combination with an offset of the focal range in the incoming radiation direction with a scanner optical unit having a dynamic zoom lens. To move the removal front within the workpiece, a movement of the workpiece that is typically slow in comparison with the scanning movement is superposed on the scanning movement. Alternatively, the removal front can be moved by virtue of the location of the movement pattern within the scanning field of the scanner optical unit being modified in the case of a stationary workpiece. It is possible to modify the location of the removal front by moving the workpiece for the purposes of producing a first section of a hollow structure and to move the removal front in the workpiece by virtue of modifying the position of the movement pattern within the scanning field for the purposes of producing a second section of the hollow structure.

In a further variant, the pulse energy of the pulsed laser radiation in the mutually offset trajectories of the movement pattern is modified to form the removal front that is not aligned perpendicular to the incoming radiation direction, with the focal region preferably being moved in a plane perpendicular to the incoming radiation direction. As an alternative or in addition to generating an offset of the focal region in the incoming radiation direction, the pulse energy of the pulsed laser radiation in the mutually offset trajectories can also be modified. Starting from a trajectory at a first lateral edge of the movement pattern, the pulse energy in this case is typically successively increased or reduced up to a trajectory at a second, opposite edge of the movement pattern. By way of example, a fast adjustment of the pulse energy can be attained with the aid of acousto-optic or electro-optic modulators, which act on a laser source for producing the pulsed laser radiation and which have response times of the order of less than 1 μs.

As a rule, the variant of the method described here is not combined with the offset of the focal region in the incoming radiation direction, and so it is possible to dispense with a device for dynamically adapting the focus location. Therefore, the pulsed laser radiation of the focal region is focused on a focal plane and moved in the focal plane when generating the ablation pattern. An F-theta lens or a telecentric lens can be used to realize the focusing of the pulsed laser radiation into a focal plane when scanning the trajectories with the aid of the scanner optical unit. At the start of the ablation process, the pulsed laser radiation can in this case be focused on a focal plane situated at the back side of the workpiece, for example.

Even if the pulsed laser radiation is focused on a focal plane perpendicular to the incoming radiation direction, an oblique removal front can be formed by modifying the pulse energy between the individual trajectories because there has been a change in the range of influence of the laser pulses: Depending on the wavelength and the pulse duration of the laser pulses, a certain threshold energy density or, alternatively, a certain threshold intensity is required to generate the removal of the workpiece material. The greater the pulse energy, the greater also the extent of the region in the incoming radiation direction in which, starting from the focal range or the focal plane, a removal of material occurs. Therefore, a fast adjustment of the pulse energy allows the formation of a removal front starting from the side of the workpiece distant from the radiation entrance side, the removal front being aligned at an angle that differs from 0° with respect to the focal plane in which the focal region is moved. In this case, too, the removal front can be moved within the workpiece by moving the workpiece in order to produce the hollow structure. In this way, an oblique removal front can be generated without requiring additional movable elements to this end, for example actuators in a zoom optical unit.

In a variant, the removal front is moved at least intermittently in a movement direction transverse to the incoming radiation direction within the workpiece during the production of the hollow structure in order to form a section of the hollow structure which preferably extends substantially parallel to the radiation entrance side, with the removal front at its side closer to the radiation entrance side preferably being aligned at an angle of less than 90°, preferably less than 70° with respect to the movement direction, when moving transversely to the incoming radiation direction. Within the meaning of this application, the phrase “substantially parallel” is understood to mean a parallel alignment or an alignment at an angle of +/−10° with respect to a parallel alignment.

The method described further above can be used, in particular, to form a “horizontal” section of a hollow structure, that is to say a section extending substantially parallel to the radiation entrance side of the workpiece. In the case of a workpiece in the form of a substrate for an EUV mirror, such a section is generally arranged at a small distance from the radiation entrance side which, in this case, corresponds to the optical surface on which the reflective coating is applied following the production of the hollow structure. The “horizontal” section allows the realization of an efficient temperature control of the optical surface of the EUV mirror.

In a further variant, the removal front is moved at least intermittently in a manner substantially parallel to the incoming radiation direction during the production of the hollow structure in order to produce a section of the hollow structure which extends substantially parallel to the incoming radiation direction, starting from the side of the workpiece that is opposite to the radiation entrance side, and in order preferably to produce a further section of the hollow structure which extends substantially parallel to the incoming radiation direction. To form a continuous hollow structure, for example in the form of a through channel, through which, following the production of the hollow structure, a fluid is able to flow for controlling the temperature, in particular cooling, of the workpiece or the substrate, it is generally necessary to connect the above-described “horizontal” section of the hollow structure to the side of the workpiece that is distant from the radiation entrance side or to any other side of the workpiece. To this end, a “vertical” channel section of the hollow structure can be produced starting from the side of the workpiece distant from the radiation entrance side, the said “vertical” channel section merging into the “horizontal” channel section of the hollow structure.

When producing the continuous hollow structure, it is possible in a first process step to produce a first “vertical” section and only a part of the “horizontal” section of the hollow structure, that is to say a hollow structure is produced which ends at a removal front within the “horizontal” section. To produce the continuous hollow structure, a second “vertical” channel section of the hollow structure is produced in a second process step, the said second “vertical” channel section starting from a different position at the side of the workpiece that is distant from the radiation entrance side, which is offset by the length of the “horizontal” section from the position at which the already produced first “vertical” section of the hollow structure starts.

The removal front during the second process step corresponds to the removal front during the first process step mirrored in the incoming radiation direction. The second “vertical” section is converted into a further part of the “horizontal” section of the hollow structure which extends level in the incoming radiation direction with the already formed part of the “horizontal” section. The two ends of the “horizontal” sections of the hollow structure are interconnected in an overlap region through continuous processing. In this way, the hollow structure is opened throughout and forms a continuous channel to which can be fed a cooling fluid via a fluid inlet at a first end, the said cooling fluid being able to be removed again from the hollow structure at a fluid outlet at the other end. A scam region is formed in the overlap region. Within the seam region, the nature of the channel, in particular the nature of the wall of the channel, differs from the nature of the channel, in particular the nature of the wall of the channel, outside of the seam region, as will be described in more detail below.

In a further variant, a first section of the hollow structure and a second, adjacent section of the hollow structure are produced, the longitudinal directions of which are aligned with respect to one another at an angle of between 70° and 100°, preferably at an angle of 90°. As described further above, the production of hollow structures with undercuts is possible in the case of the method described here. By way of example, a hollow structure in the form of a curved cooling channel can be produced with the aid of the method described here. In particular, it is possible to produce a hollow structure having a 90° curve, that is to say having a directional change of approx. 90° between adjacent sections. By way of example, this is beneficial to the formation of the above-described transition between the “vertical” section of the hollow structure and the “horizontal” section of the hollow structure. However, it is understood that the transition, described here, in the style of a curve through approx. 90° need not necessarily occur between a “horizontal” and a “vertical” section of the hollow structure.

In a variant, a rounded-off section is formed during the production of the hollow structure, the first section and the second section merging into one another in the said rounded-off section. It was found to be advantageous that no discontinuous transition in the form of a kink is produced in the case of the curvature of approx. 90° between the two adjacent sections, but rather that the transition is implemented continuously along a rounded-off section of the hollow structure. As a rule, the rounded-off section has a constant radius of curvature; however, this is not mandatory, that is to say the radius of curvature may vary. The rounded-off section simplifies tracking by a flexible tubing in order to feed a flux to the removal front or the hollow structure, which flux effectively removes removal products from the region of the removal front, as will be described in more detail below.

In a further variant, the removal front is brought into contact with a fluid during the production of the hollow structure, with the fluid tracking the removal front with a fluid feed when the removal front moves, the fluid feed being at least partially introduced into the hollow structure. It is typically necessary to rinse the focal region with a liquid that is in particular transparent to the pulsed laser radiation, in order to remove ablation products and in order to cool the workpiece. The liquid can be guided to the back side of the workpiece in the form of a free liquid jet with the aid of a nozzle, or the workpiece can be partially immersed in a liquid bath. However, instead of a liquid, a gas, for example compressed air, can be brought into contact with the removal front in order to remove the ablation products.

Should the hollow structure, for example in the form of a channel, have a long length, it is necessary for the fluid feed to be at least partially introduced into the hollow structure in order to enable local rinsing in the region of the removal front. For this purpose, the fluid feed or a part of the fluid feed, for example a nozzle, may be at least partially introduced into the hollow structure. By way of example, the fluid feed can be formed as a rigid pipe or comprise a rigid pipe, a nozzle being attached to the free end thereof, with the pipe or the nozzle being at least partially introduced into the hollow structure. However, it is also possible that the fluid feed has no nozzle. The fluid feed, for example in the form of the pipe, has an external diameter that is slightly smaller than the diameter of the hollow structure so that the fluid emerging from the nozzle can be removed via an interstice between the pipe and the wall of the hollow structure.

In a development of this variant, the fluid feed comprises at least one flexible tubing or the fluid feed forms at least one flexible tubing and the removal front is tracked by the fluid with the at least one flexible tubing, in particular starting from a side of the workpiece that is distant from the radiation entrance side.

When producing a curved hollow structure, which optionally has a 90° curve or a 90° bend, a flexible tubing has to be introduced into the already produced part of the hollow structure for the effective removal of the removal products. The free end of the tubing, to which a nozzle is typically attached, is positioned at a comparatively short distance from the removal front in this case. The tubing has a diameter which is slightly smaller than the diameter of the hollow structure in order to ensure that the fluid emerging from the nozzle can be removed via an interstice between the tubing and the wall of the hollow structure, typically in the direction toward the back side of the workpiece. Other flexible elements which have a free end or an end piece for the emergence of a fluid may track the removal front.

In a further variant, the workpiece is moved, in particular displaced, for moving the removal front. By way of example, the workpiece movement can be implemented in the form of a displacement in one, in two or in three spatial directions. Particularly if there should be a transition between two sections of the hollow structure which are aligned at approx. 90° with respect to one another, it is advantageous if the workpiece is displaced or moved in two spatial directions within a superposed movement. For the production of hollow structures whose size does not exceed the processing field of the scanner optical unit, the movement of the removal front within the workpiece may also be realized by a movement of the scanning pattern within the processing field, without the workpiece being moved in the process. In this case, too, the alignment of the removal front can be modified relative to the incoming radiation direction when producing the hollow structure.

In a further variant, the focal region is moved along mutually offset trajectories of the movement pattern with a scanner optical unit in order to form the removal front. The movement of the focal region to form the removal front is implemented in this case by a fast deflection of the pulsed laser radiation with the aid of the scanner optical unit, which may for this purpose comprise, for example, one or more scanner mirrors, for example in the form of galvanometer mirrors. To produce the hollow structure, the scanning movement for forming the removal front is typically superposed on the comparatively slow movement of the workpiece. To focus the focal region in a focal plane during the scanning movement, it is typically necessary for the pulsed laser radiation to pass through an F-theta lens or a telecentric lens. When generating an offset of the focal region in the incoming radiation direction for forming the oblique removal front, such a lens is generally likewise used in combination with a dynamic zoom lens. As a rule, an F-theta lens or a telecentric lens is also used when generating an oblique removal front by modifying the pulse energy of the pulsed laser radiation.

In a further variant, the hollow structure has a round cross section with a diameter of between 1 mm and 20 mm, preferably between 1 mm and 5 mm. As described further above, the channel may also have a cross section which deviates from a round cross section. In this case, the diameter of the channel is understood to be what is known as the equivalent diameter, that is to say the diameter of a circle whose area corresponds to the flow cross section of the channel, which is not circular in this case. For the flow of a fluid, channels with a diameter in the aforementioned value range were found to be advantageous.

In a further variant, the hollow structure has a length of at least 10 cm, preferably of at least 15 cm, particularly preferably of at least 20 cm, in particular of at least 70 cm. As described further above, hollow structures in the form of curved channels with a significant length, in particular, can be produced with the aid of the method described here.

The invention also relates to a method of the type set forth at the outset, which in particular may also comprise one or more variants of the above-described method. In the method, the hollow structure away from the removal front is delimited by a lateral surface, the removal front during the production of the hollow structure being aligned at a removal front angle with respect to a region of the lateral surface of the hollow structure adjacent to the removal front, and the removal front angle being, at least intermittently, greater than a removal front minimum angle of 1° and being, at least intermittently, less than a removal front maximum angle of 89°. The removal front minimum angle preferably is 5°, 10°, 20° or 30°. The removal front maximum angle preferably is 85°, 80°, 70° or 60°. The removal front angle during the production of the hollow structure may be permanently greater than the removal front minimum angle and/or permanently less than the removal front maximum angle, but this is not mandatory. The lateral surface may be a cylindrical lateral surface, for example; however, this is not mandatory. By way of example, the hollow structure can be a channel through which a fluid is preferably able to flow.

The invention also relates to a method for producing a channel, through which in particular a fluid is able to flow, in a workpiece in the form of a substrate for a mirror, in particular for an EUV mirror, with the channel being produced by material-removing processing with pulsed laser radiation and with a fluid feed being at least partially introduced into the channel during the production of the channel. As described further above, the production of a channel with a comparatively long length requires the use of a fluid feed which is at least partially introduced into the channel.

In a variant of the method, a fluid is fed with the aid of the fluid feed into a region in which the material-removing processing is carried out, in particular to a removal front formed during the material-removing processing, with the removal front preferably being tracked, in particular in automated fashion, by the fluid feed when the removal front is moved in the workpiece. Within the scope of the material-removing processing with pulsed laser radiation, which for example may be carried out with the method described further above, the production of long channels requires tracking of the removal front by the fluid feed for cooling the removal front and for removing the ablation products. By way of example, the fluid feed can be a pipe or the like, the free end of which, to which a nozzle may have been attached, typically being arranged at a small distance from the removal front. Tracking the removal front with the fluid is also required in the case where a straight-line channel of significant length is produced. In this case, it may be possible to optionally dispense with the above-described oblique alignment of the removal front. By way of example, automated tracking can be implemented with the aid of the tracking device described below.

In a further variant, the fluid feed comprises a flexible element which is at least partially introduced into the preferably curved channel, the flexible element preferably forming a flexible tubing. As described further above, the introduction of a flexible element, for example in the form of a flexible fluid line in the form of a flexible tubing, allows tracking of the removal front by the fluid even if the channel is curved and has undercuts, for example in the form of a 90° deflection or the like.

In a further variant, the channel is produced with a length of at least 10 cm, preferably of at least 15 cm, particularly preferably of at least 20 cm, in particular of at least 70 cm. As described further above, tracking is required when a channel of comparatively long length is produced. As described further above, the channel is produced through material-removing processing with pulsed laser radiation. It is possible that sections produced in a different manner, for example by mechanical processing, for example by drilling, are adjacent to the channel. The lengths of these sections remain unconsidered when determining the length of the channel.

The substrate is monolithic in a further variant. To avoid stress in the substrate material to the best possible extent, which stress occurs when joining two or more partial bodies to form a substrate, it is advantageous if the substrate of the mirror, for example of the EUV mirror, is formed monolithically, that is to say in one piece. With the aid of the method described further above, it is possible to produce hollow structures with virtually any desired geometry in such a monolithic substrate. The hollow structure or structures can be cooling channels, in particular, that is to say hollow structures that allow the passage of a cooling liquid, for example water. The hollow structure can be a continuous cooling channel; however, it is also possible that the hollow structure has one or more branching points. A coolant inlet and a coolant outlet for the hollow structure may be arranged on the back side of the substrate; however, this is not mandatory, especially if other material-removing methods are additionally used for the production of the entire hollow structure or of a plurality of hollow structures.

In a variant, the substrate consists of titanium-doped fused silica or a glass ceramic. As described further above, a substrate for an EUV mirror typically consists of what is known as a zero-expansion material, which has an extremely small coefficient of thermal expansion.

In principle, hollow structures may also be introduced, in the manner described above, into workpiece materials that are unsuitable for use as a substrate for an EUV mirror. Workpiece classes suitable for the method are glasses, crystals and semiconductors. A precondition is that the respective material is transparent to the incoming laser radiation. For silicon, by way of example, this is the case at wavelengths in the near infrared wavelength range of more than approx. 1060 nm.

In a further variant, the material of the substrate has a zero-crossing temperature which is between 0° C. and 100° C., preferably between 19° C. and 40° C., particularly preferably between 19° C. and 32° C. Zero-expansion materials, for example in the form of doped fused silica, in particular in the form of titanium-doped fused silica, or in the form of certain glass ceramics, pit components or phases with positive and negative coefficients of thermal expansion against one another. This results in an effectively non-linear relationship between thermal expansion and temperature, with there being exactly one temperature value for which the thermal expansion vanishes or is the least sensitive to changes in the temperature; to be precise, this is what is known as the zero-crossing temperature, which is also referred to as ZCT.

In a variant, the material of the substrate has a spatial variation of the zero-crossing temperature which is less than 3 K, preferably less than 2 K, particularly preferably less than 1 K, in particular less than 0.1 K. It is advantageous if the zero-crossing temperature is as constant as possible, that is to say exhibits as little variation as possible, over the entire volume of the substrate. The spatial variation is understood to mean the difference between the maximum zero-crossing temperature and the minimum zero-crossing temperature in the volume of the substrate. The spatial variation of the zero-crossing temperature relates to the substrate following the production of the hollow structure in the substrate, that is to say the material ablated during the production of the hollow structure remains unconsidered when determining the spatial variation of the zero-crossing temperature.

The invention also relates to a mirror, in particular an EUV mirror, comprising: a substrate and a coating applied to the substrate and serving to reflect radiation, in particular EUV radiation, the substrate comprising at least one hollow structure, preferably in the form of a channel, particularly preferably in the form of a channel through which a fluid is able to flow, in particular in the form of a cooling channel through which a cooling fluid is able to flow, produced using the above-described method. As a rule, the hollow structure serves for the temperature control of the EUV mirror and a fluid is passed therethrough to this end. However, the hollow structure may also be introduced into the substrate for any other purpose, for example in order to integrate one or more components, for example in the form of sensors, actuators, etc., into the substrate. The substrate typically does not yet have a reflective coating when the hollow structure is produced, so as to avoid an interaction arising between the pulsed laser radiation and the materials of the reflective coating. Therefore, the reflective coating is typically only applied to the substrate following the production of the hollow structure.

The invention also relates to a mirror, in particular an EUV mirror, comprising: a substrate comprising at least one channel through which a fluid is preferably able to flow, the channel being formed through material-removing processing with pulsed laser radiation, the channel having a curved form and the channel having a diameter of between 1 mm and 20 mm, preferably between 1 mm and 5 mm, and/or a length of at least 10 cm, preferably at least 15 cm, in particular at least 20 cm. The channel may have been formed during the material-removing processing with pulsed laser radiation, in particular in the manner described above, that is to say with the above-described method, by virtue of a removal front that moves through the substrate being formed with the pulsed laser radiation. In particular, the removal front in this case, at least intermittently, may not be aligned perpendicular to the incoming radiation direction of the pulsed laser radiation at the radiation entrance side of the workpiece. The curved channel may be formed in particular for the passage of a fluid, for example a cooling fluid.

The substrate is monolithic in an embodiment. As described above, stress in the substrate material, which occurs when two or more partial bodies are joined to form a multi-part substrate, may be avoided in a monolithic substrate.

In a further embodiment, the channel has a first section and a second, adjacent section, the longitudinal directions of which are aligned with respect to one another at an angle of between 70° and 100°, preferably at an angle of 90°. Deflections at a comparatively large angle of approx. 90° may be advantageous when guiding a fluid through the channel in order to bring about effective temperature control of the substrate.

In an embodiment, the first section and the second section merge into one another in a rounded-off section. A continuous transition between the two sections along a rounded-off section was found to be advantageous vis-à-vis a transition in the form of a kink, as will be described in more detail below.

A further aspect of the invention relates to an optical element for reflecting radiation, in the form of the mirror, in particular an EUV mirror, comprising: a preferably monolithic substrate, a reflective coating for reflecting radiation, in particular EUV radiation, the coating being applied to a surface of the preferably monolithic substrate, and at least one hollow structure which extends in the preferably monolithic substrate and is designed to allow a fluid to flow therethrough, with the hollow structure having a first section and a second, neighboring section, which are aligned with respect to one another at an angle of between 60° and 120°, preferably at an angle of between 80° and 100°, in particular at an angle of 90°, and the hollow structure having a rounded-off section, at which the first section and the second section merge into one another. The two sections typically are channel sections that typically extend substantially in a straight line immediately adjacent to the rounded-off section. Immediately adjacent to the rounded-off section, the two sections have longitudinal axes aligned with respect to one another at the above-described angle. In particular, the first section and the second section may be aligned with respect to one another at an angle of more than 90°, for example of more than 100°.

A flow separation, which leads to turbulence and causes flow-induced vibrations, may arise at the wall of the hollow structure at a transition between two sections of the hollow structure of the substrate in the form of a corner or a sharp edge, especially if the two sections are aligned approximately perpendicular to one another, that is to say at an angle of between 60° and 120° with respect to one another. For this reason, it is proposed that the two sections of the hollow structure merge into one another at a rounded-off section, which has a profile that is as streamlined as possible.

A rounded-off section is understood to mean a section without corners. Consequently, the first section merges continuously into the second section at the rounded-off section. The cross section or the diameter of the hollow structure is typically constant within the rounded-off section, but optionally it may also vary. As a rule, the cross section or the diameter of the rounded-off section corresponds to the cross section of the two sections, but this is not mandatory if the rounded-off section is arranged at a branching point; see below.

The substrate is preferably monolithic, that is to say it is formed in one piece, and has no joining surface, at which two or more partial bodies of the substrate are interconnected.

The rounded-off section can be produced by material-removing processing with pulsed laser radiation, as described above in the context of the method for producing a hollow structure or for producing a channel, in which the removal front aligned obliquely with respect to the incoming radiation direction is formed. As described above, hollow structures that deviate from a straight-line geometry and, in particular, do not extend parallel to the thickness direction of the substrate can be formed by the oblique alignment of the processing plane or removal front. By way of example, the rounded-off section of the hollow structure may be produced by virtue of the oblique removal front being simultaneously displaced in two mutually perpendicular directions.

In an embodiment, an R/D ratio between a radius of curvature R of the rounded-off section and a diameter D of the rounded-off section is between 2 and 6, preferably between 2.5 and 5, in particular between 2.5 and 3.5. Significant improvements in relation to the flow-induced vibrations, for example >50%, can already be achieved in the case of an R/D ratio of more than 2. Ideally, the R/D ratio is between approx. 2.5 and 3.5, for example 3.0, since the greatest improvements in relation to the flow-induced vibrations are typically attained there. The R/D ratio should not exceed a value of more than 6. In this embodiment, the rounded-off section has a constant radius of curvature.

The flow cross section of the rounded-off section is typically circular but may optionally also deviate from a circular geometry and for example have an elliptical geometry. In this case, the diameter of the rounded-off section is understood to be what is known as the equivalent diameter, that is to say the diameter of a circle whose area corresponds to the flow cross section of the rounded-off section, which is not circular in this case, as already described above.

It was found that the ratio between the diameter of the rounded-off section and the radius of curvature of the rounded-off section represents a salient parameter for a streamlined flow guidance without turbulence, and consequently for the avoidance of flow-induced vibrations.

In a further embodiment, the diameter D of the rounded-off section is between 2 mm and 20 mm, preferably between 2 mm and 12 mm. A diameter of the rounded-off section or of the channel structures of the hollow structure of the specified order of magnitude allows the generation of a sufficient volumetric flow rate for efficient temperature control of the optical element for the given boundary conditions. As a rule, the flow speed of the fluid within the hollow structure is of the order of metres per second.

In an embodiment, the hollow structure comprises a plurality of temperature control channels, in particular in the form of cooling channels, which extend below the surface to which the reflective coating is applied, and the hollow structure comprises a fluid distributor connected to the temperature control channels, in particular to the cooling channels, via distributor channels, and a fluid collector connected to the temperature control channels, in particular to the cooling channels, via collector channels. The temperature control channels, which usually serve to cool the substrate and therefore are also referred to as cooling channels below, generally extend in a surface-near region below the surface. A surface-near region is understood to mean a distance from the surface of the substrate of 10 mm or less. The distance from the surface is measured in the thickness direction of the substrate, the latter generally being aligned perpendicular to the generally planar lower side of the substrate. Effective cooling of the surface of the mirror can be brought about as a result of the small distance of the cooling channels from the surface. The distance is understood to mean the minimum distance between the respective temperature control channel and the surface with the reflective coating.

As a rule, the fluid distributor and the fluid collector each have a greater flow cross section than an individual cooling channel. This makes the setting of beneficial flow conditions possible. The fluid distributor and/or the fluid collector are preferably arranged at a greater distance from the surface to which the reflective coating is applied than the cooling channels. This arrangement allows the deformation of the surface owing to the fluid pressure in the fluid distributor and/or in the fluid collector, which generally have cavities with a greater surface area than the cooling channels, to be kept within acceptable limits. The fluid distributor is typically connected to a fluid inlet and the fluid collector is typically connected to a fluid outlet. Each respective cooling channel may be connected to precisely one distributor channel and precisely one collector channel; however, as a matter of principle, it is also possible that a group of two or optionally more than two cooling channels is connected to a common distributor channel and to a common collector channel.

In a further embodiment, the first section forms an end section of the temperature control channel, in particular of the cooling channel, adjacent to a distributor channel, and the second section forms a distributor channel section adjacent to the end section, and/or the first section forms an end section of the temperature control channel, in particular of the cooling channel, adjacent to a collector channel, and the second section forms a collector channel section adjacent to the end section.

The cooling channels typically extend substantially parallel to the surface to which the reflective coating is applied. Since the installation space within the substrate is limited, a distributor channel or a collector channel, which is connected to a respective cooling channel, is generally led away from the surface with the reflective coating at approximately right angles, that is to say the collector or distributor channel section and an adjacent end section of the cooling channel typically extend at approximately right angles to one another, that is to say there is approximately a 90° deflection of the fluid which flows through the hollow structure.

The above-described rounded-off section allows avoidance of, or at least substantial reduction in, flow-induced vibrations, in particular with the choice of a suitable ratio of radius of curvature to diameter.

In principle, the fluid distributor and the fluid connector may have different designs. By way of example, the flow cross section of the fluid distributor and of the fluid collector may taper starting from the distributor channels and from the collector channels, respectively, for example in the style of a funnel, such that the cavities formed by the fluid distributor and the fluid collector in the substrate are not unnecessarily large.

In a further embodiment, the fluid distributor forms an inlet channel, from which the distributor channels branch off, and/or the fluid collector forms an outlet channel, from which the collector channels branch off. In this embodiment, the fluid collector and the fluid distributor generally extend substantially transverse to the longitudinal direction of the distributor channels and transverse to the longitudinal direction of the collector channels. As a rule, the distributor channels and the collector channels branch off the inlet channel and the outlet channel, respectively, at substantially right angles. By way of example, the fluid distributor and the fluid collector may be formed as cylindrical channels in this case, which extend into the substrate starting from an inlet opening and an outlet opening, respectively, on an outer side of the substrate. In this case, the inlet channel and the outlet channel may be formed as drilled holes, for example; however, it is also possible for these to be produced by the ablation method described above.

In a development of this embodiment, the first section forms a merging section of the distributor channel neighboring the inlet channel, and the second section forms a branching section of the inlet channel neighboring the merging section, and/or the first section forms a merging section of the collector channel neighboring the outlet channel, and the second section forms a branching section of the outlet channel neighboring the merging section of the collector channel.

As described further above, the longitudinal direction of the inlet channel and of the outlet channel extends substantially perpendicular to the longitudinal direction of the respective collector channel and distributor channel, respectively. At a respective branching point of a distributor or collector channel, a streamlined geometry which may be produced by the provision of a rounded-off section at a branching point of the inlet channel or outlet channel is also advantageous. Steps can be avoided and edges can be rounded-off thereby, as a result of which the geometry of the hollow structure can be designed in more streamlined fashion and the separation of the fluid in the inlet channel and in the outlet channel can be avoided or at least significantly reduced.

The ratio of diameter to radius of the rounded-off section is preferably within the value range described above. However, the rounded-off section may not have a constant radius of curvature at the branching point. The flow diameter of the rounded-off section at the branching point need not necessarily be constant either. By way of example, the cross section of the rounded-off section may taper starting from the inlet channel or starting from the outlet channel.

In a further embodiment, the angle between the branching section of the inlet channel and the merging section of the distributor channel is greater than 90°, preferably greater than 100°, and/or the angle between the branching section of the outlet channel and the merging section of the collector channel is greater than 90°, preferably greater than 100°. It was found that it is beneficial to the flow guidance if the branching section of the inlet channel and outlet channel and the branching section of the distributor channel and collector channel, respectively, are aligned at an obtuse angle with respect to one another.

In a further embodiment, the material of the substrate is selected from the group comprising: fused silica, in particular titanium-doped fused silica, and glass ceramic. To avoid a deformation of the surface to which the reflective coating is applied, which deformation can be traced back to possibly inhomogeneous heating of the substrate material, the substrates of mirrors for EUV lithography are typically produced using what is known as zero-expansion material which has a very small coefficient of thermal expansion; see above. As described above, these materials are hard and brittle and can therefore be mechanically processed only with difficulties. However, hollow structures of practically any shape can also be produced in such materials using the above-described methods for laser ablation.

In a further embodiment, the material of the substrate has a zero-crossing temperature which is between 0° C. and 100° C., preferably between 19° C. and 40° C., particularly preferably between 19° C. and 32° C. As described above, the zero-crossing temperature is determined, inter alia, depending on the mean incident radiant flux during the operation of the EUV mirror.

In an embodiment, the material of the substrate has a spatial variation of the zero-crossing temperature which is less than 3 K, preferably less than 2 K, particularly preferably less than 1 K, in particular less than 0.1 K. As described above, a high spatial homogeneity of the zero-crossing temperature is typically required for efficient operation of the mirror.

In a further embodiment, the hollow structure, preferably the channel through which in particular a fluid is able to flow, has a seam region. As described above, a seam region is typically formed during the production of a hollow structure in the form of a channel, in which seam region two parts of the channel formed by laser ablation are brought together for forming a continuous channel. Within the seam region, the nature of the channel, in particular of the wall of the channel, differs in terms of at least one property from the nature of the channel, in particular of the wall of the channel, outside of the seam region. By way of example, the surface or a surface structure on the wall of the channel in the seam region may differ from the surface or a surface structure on the wall of the channel outside of the seam region.

In a development of this embodiment, the hollow structure, preferably the channel through which in particular a fluid is able to flow, has an edge contour of a removal front, at least one bulge, a lateral offset or another structural modification in the seam region.

In the seam region, the outline or the edge contour of the removal front, or optionally of the two removal fronts, where the laser ablation of the respective part of the channel was terminated may be identifiable in, or written into, the surface structures of the hollow structure in the form of the channel. The edge contour of the removal front identifiable in the surface structure of the channel may in particular be at an angle, for example an angle of 45°, with respect to a region of the lateral surface of the channel adjacent to the removal front. The angle can typically be traced back to the fact that the removal front was not aligned perpendicular to the incoming radiation direction during the production of the channel. The edge contour of the removal front may be identifiable over the complete perimeter or optionally only in sections of the surface structure of the channel.

One or more bulges, which each form, locally delimited in the longitudinal direction, an increase or reduction of the cross section of the channel, may occur on the wall of the channel within the seam region. Additionally, the wall of the channel may have a minor lateral offset in the style of a step within the seam region, which step arises during the bringing together of the two parts of the channel and/or on account of slightly different cross sections of the two parts of the channel. It is understood that the nature of the channel or of the wall of the channel in the seam region may also have other structural modifications which distinguish the surface structure of the channel within the seam region from the surface structure of the channel outside of the seam region.

A further aspect of the invention relates to a mirror, in particular an EUV mirror, comprising: a substrate which comprises an in particular curved channel through which a fluid is preferably able to flow, the said channel having a seam region. As described above, the seam region arises if two parts of the channel formed by laser ablation are brought together to form a continuous channel. The seam region is typically spaced apart from both ends of the channel. The seam region may have approximately the same distance from both ends of the channel, but this is not mandatory. As described above, the nature of the channel, in particular of the wall of the channel, within the seam region differs in terms of at least one property from the nature of the channel, in particular of the wall of the channel, outside of the seam region.

In an embodiment, the channel has an edge contour of a removal front, at least one bulge, a lateral offset or another structural modification in the seam region.

The mirror according to the present aspect of the invention may in particular have the features of the mirrors according to the above-described aspects of the invention. The substrate material may be titanium-doped fused silica or a glass ceramic, in particular. The substrate may have a monolithic form, but this is not mandatory.

A further aspect of the invention relates to an EUV lithography system, comprising: at least one EUV mirror designed as described above and a temperature control device, in particular a cooling device, designed to allow a temperature control fluid, in particular a cooling fluid, to flow through the at least one hollow structure, which in particular is in the form of a channel. The EUV lithography system can be an EUV lithography apparatus for exposing a wafer, or can be some other optical arrangement that uses EUV radiation, for example an EUV inspection system, for example for inspecting masks, wafers or the like that are used in EUV lithography.

The temperature control device may serve as a cooling device and, for example, may be formed to allow a coolant in the form of a cooling fluid, for example a cooling liquid, for example in the form of cooling water, to flow through the hollow structure, in particular in the form of the channel. For this purpose, the temperature control or cooling device may optionally have a pump and also suitable feed and removal lines. The temperature control device may also serve as a heating device for heating the substrate. In this case, a temperature control fluid in the form of a heating fluid, which generally likewise is a liquid, is fed to the hollow structure in the form of the channel. It is also possible that the temperature control device is designed to both heat and cool the mirror. Water is preferably used as the temperature control fluid to be passed through the hollow structure in the form of the channel-both in the case of cooling and heating.

The hollow structure of the substrate has an inlet opening for the entrance of the fluid and an outlet opening for the exit of the fluid. The inlet opening and the outlet opening may be connected to a port of a fluid supply line and a fluid removal line, respectively, in order to connect the channel to the temperature control device. Should a plurality of fluidically separated hollow structures or channels extend within the substrate, these are connected to the temperature control device through separate inlet and outlet openings.

A further aspect of the invention relates to an apparatus of the type set forth at the outset, the apparatus comprising a fluid feed which is at least partially introducible into the channel. The apparatus is designed to carry out the above-described method for producing a channel, within the scope of which material-removing processing is carried out and within the scope of which the fluid feed is at least partially introduced into the channel. As described above, relatively long channels require removal of the ablated workpiece material with the aid of a suitable fluid feed and cooling of the removal front.

In an embodiment, the fluid feed is designed to feed, with the aid of the fluid feed, a fluid to a region in which the material-removing processing is carried out, in particular to a removal front formed during the material-removing processing, the fluid feed preferably being able to track the removal front during its movement in the workpiece. To this end, the fluid feed may remain stationary and the workpiece may be moved relative to the fluid feed; however, it is also possible that the fluid feed itself is moved with the aid of suitable actuators or the like. In this case, the fluid feed typically comprises an element that can be introduced into the channel, for example in the form of a pipe or the like.

In a further embodiment, the fluid feed is designed to at least partially introduce a flexible element, in particular a flexible tubing, into the channel. To remove the ablated material as effectively as possible from the removal front, the fluid needs to be fed to the vicinity of the removal front, especially if this relates to a curved channel, with the aid of a flexible tubing or the like. At the free end, the flexible tubing may have a nozzle for the emergence of the fluid, which may be water or compressed air for example. In the case of non-angled cavities or comparatively short cavity lengths of, e.g., less than 20 mm, typically in the case of a distance between the removal front and the emergence of the fluid from the tubing or nozzle, it is possible for the flexible tubing to be arranged in a stationary fashion and to be automatically introduced into the cavity on account of the movement of the workpiece, without there being an external action on the tubing for this purpose. The apparatus described here may comprise a fluid provision device and optionally a tracking device for automated tracking of the removal front by the flexible tubing, as described in the context of the fluid feed apparatus described below.

In a further embodiment, the scanner optical unit is designed to move the focal region along a movement pattern in order to form a removal front for the areal removal of material of the workpiece, the apparatus being designed to form a removal front that is not aligned perpendicular to an incoming radiation direction of the pulsed laser radiation at the workpiece received by the holder. Typically, the incoming radiation direction at the workpiece, more precisely at the radiation entrance side of the workpiece, corresponds to the direction of gravity. When arranged in the holder, the workpiece is aligned so that its thickness direction, which typically runs perpendicular to the radiation entrance side, corresponds to the direction of gravity. The laser source is designed to produce pulsed laser radiation in the form of ultrashort laser pulses, which typically allow generation of a multi-photon absorption for ablating the material of the workpiece.

There are numerous options for the design of the apparatus for aligning the removal front in a direction or in a plane not aligned perpendicular to the incoming radiation direction.

In an embodiment, the apparatus additionally comprises a focus offset device for offsetting the focal region of the pulsed laser radiation in or along the incoming radiation direction of the pulsed laser radiation and a control device which is designed or programmed to control the focus offset device to offset trajectories of the movement pattern with respect to one another in or along the incoming radiation direction in order to form the removal front that is not aligned perpendicular to the incoming radiation direction.

In this embodiment, the apparatus comprises a focus offset device for dynamically offsetting the focal region along the incoming radiation direction of the pulsed laser radiation. By way of example, the focus offset device can be formed as a dynamic zoom lens. The control device may be implemented in the form of suitable hardware and/or software.

In a further embodiment, the apparatus comprises a control device which is designed or programmed to control the laser source to modify a pulse energy of the pulsed laser radiation of mutually offset trajectories of the movement pattern in order to form the removal front that is not aligned perpendicular to the incoming radiation direction. As described above in the context of the method, the pulsed laser radiation is focused on a plane typically aligned perpendicular to the incoming radiation direction with the aid of the focusing optical unit, without the use of the focus offset device. To focus the pulsed laser radiation in the same focal plane at all positions in the scanning field of the scanner optical unit, the apparatus may comprise an F-theta lens or a telecentric lens. To align the removal front at an angle with respect to the focal plane in which the focal region is moved, the pulse energy of the pulsed laser radiation is modified between the mutually offset trajectories in this case.

To modify the pulse energy, the laser source may comprise one or more acoustic-optical or electro-optical modulators, on which the control device acts. As described above in the context of the method, the pulse energy generally increases or decreases from one edge of the ablation pattern to the opposite edge of the ablation pattern, as a result of which a removal front which is aligned at an angle with respect to the focal plane is formed.

In a further embodiment, the apparatus comprises a positioning device for moving the removal front within the workpiece, preferably starting from a side of the workpiece that is opposite to the radiation entrance side, for the purposes of producing the channel, the positioning device being designed to displace the workpiece in or along the incoming radiation direction and preferably in or along at least one direction transverse to the incoming radiation direction. To this end, the positioning device typically acts on the holder of the workpiece. The positioning device may comprise one or more drives, for example in the form of linear motors or the like, which in particular realize a superposed movement or displacement of the workpiece in two or three different spatial directions. In principle, it is also possible that the positioning device is designed to rotate the workpiece.

A further aspect of the invention relates to a fluid feed apparatus of the type set forth at the outset, comprising: at least one flexible fluid line, preferably a plurality of flexible fluid lines, for feeding the fluid to the at least one removal front, preferably to a plurality of removal fronts, and an insertion component for insertion into a cavity of the workpiece, the insertion component having at least one guide channel in which the at least one flexible fluid line is guided or the at least one flexible fluid line is able to be guided in order to feed the fluid to the at least one removal front.

For the feed of the fluid to the at least one removal front which is moved in the material of the workpiece when producing a hollow structure, the fluid feed apparatus according to this aspect of the invention comprises at least one flexible fluid line, which is able to track the removal front during the movement thereof through the workpiece. To position the flexible fluid line, more precisely the free end thereof from which the fluid emerges, at a specified position within the substrate in the case of the fluid feed apparatus according to the invention, the flexible fluid line is guided in a guide channel of an insertion component inserted into a cavity in the workpiece.

This is particularly advantageous if one or more structures formed by laser ablation, in particular by multi-photon laser ablation, branch off from a wall of the cavity because in this case, with the aid of the insertion component or the guide channel, the respective end of the fluid line can be positioned at a position at the wall of the cavity from which the structure emanates, and the removal front can be tracked when the structure is formed.

It is possible that a short section of the respective structure branching off from the cavity has already been produced by laser ablation prior to the insertion of the insertion component into the cavity. To feed a fluid to the removal front formed in the process, the workpiece may be at least partially immersed in a liquid bath. As soon as the removal front has a distance of typically more than approx. 20-40 mm from the wall of the cavity, the immersion into the liquid bath is generally no longer sufficient since the ablated material can no longer be removed to a sufficient extent, and the ablation process grinds to a halt. To produce structures which branch off from the cavity and which have a length greater than approx. 20-40 mm, the movement of the removal front is therefore tracked by the fluid with the aid of a flexible fluid line.

A flexible fluid line may also track the removal front even without an insertion component provided that the hollow structure produced by the laser ablation does not branch or have any other geometry that is too complex. However, with the aid of the insertion component, the flexible fluid line can be positioned at the position from which a structure should start or branch off from the cavity, as described above. Therefore, with the aid of the insertion component, it is possible to ensure the feed of the fluid to the removal front even in the case of a hollow structure with branching points, without this requiring manual threading of the flexible fluid line or the flexible fluid lines into the structure branching off from the cavity or into the structures branching off from the cavity.

The laser ablation can be implemented in the form of a multi-photon laser ablation, in particular. In order to form a hollow structure in the case of the multi-photon laser ablation, the pulsed laser radiation, generally ultrashort pulse laser radiation, is radiated through the material of the substrate to a point on the back side of the workpiece or on a surface within the workpiece, for example on a wall of the above-described cavity, from which point the structure to be formed should start. In the case of multi-photon laser ablation, a removal front is produced which, starting from this point, is moved through the material of the substrate in order to form the hollow structure. Regarding details with respect to the removal of material through multi-photon laser ablation, reference is made to the above-described method for producing a hollow structure through material-removing processing with pulsed laser radiation. As described there, the removal front or the processing plane, for the purposes of producing hollow structures with complex geometries, may be aligned so as not to be perpendicular to the incoming radiation direction of the pulsed laser radiation but instead be tilted in relation to a plane perpendicular to the incoming radiation direction. Thereby, it is possible also to produce, through laser ablation, hollow structures that are not in a straight line and have undercuts.

The fluid is typically a liquid, for example water, which emerges at a comparatively high pressure from the flexible fluid line. Instead of a liquid, a gas, for example compressed air, can be brought into contact with the removal front in order to remove the ablation products. A nozzle for the emergence of the fluid may be attached to the free end of the flexible fluid line or tubing, but this is not mandatory.

The workpiece preferably is an in particular monolithic substrate for an EUV mirror. A monolithic substrate is formed in one piece, and has no joining surface, at which two or more partial bodies of the substrate are interconnected. As described above, hollow structures in such a monolithic substrate cannot be readily produced by mechanical processing, for example by drilling or grinding, in the hard and brittle glass material, which may be titanium-doped fused silica or a glass ceramic, for example. The above-described cavity can be produced by mechanical processing, for example the cavity may be a hole which is milled into the substrate. However, it is also possible that the cavity is produced by multi-photon laser ablation, even if this method is time-consuming when producing cavities with large diameters.

In an embodiment, the insertion component has a plurality of guide channels in which a flexible fluid line is guided in each case. In the case of a hollow structure which optionally has a significant number of channels or other structures emanating from the cavity, it is therefore advantageous to produce the plurality of channels or other structures simultaneously. To this end, a plurality of pulsed laser beams can be radiated simultaneously through the volume of the workpiece in order to simultaneously form a plurality of removal fronts at which the material of the workpiece is ablated, as a result of which a plurality of structures or channels branching off from the cavity are able to be produced simultaneously.

The simultaneous generation of a plurality of removal fronts requires the simultaneous feed of the fluid to the removal fronts with the aid of a corresponding number of guide channels or flexible fluid lines, which track the respective removal fronts. Ideally, all structures branching off from the cavity can be produced concurrently. If the number of structures to be branched off is too large, these structures may be divided into a plurality of groups, which are each processed together concurrently. Differently formed insertion components can be used for the production of a respective group of structures.

In a further embodiment, a gap through which fluid can flow, in particular a ring gap, is formed between the fluid line and a channel wall of the guide channel in order to return the fluid from the removal front. The flexible fluid line has a diameter chosen such that the fluid fed to the removal front in the fluid line can be removed again via the passable gap. As a rule, the flow cross section of the gap should at least correspond to the flow cross section of the fluid in the flexible fluid line.

In a further embodiment, the guide channel has at least one rounded-off section for changing the direction of the flexible fluid line. As a rule, the structures that branch off from the cavity in the workpiece do not extend parallel to the direction along which the insertion component is inserted or introduced into the workpiece. Therefore, if the respective guide channel starts from the end face of the insertion component, it is generally necessary to change the direction of the flexible fluid line within the insertion component. Such a directional change is ideally implemented by the guide of the fluid line along a rounded-off or curved section of the guide channel. At the rounded-off section, there preferably is a directional change of the flexible fluid line at an oblique angle, that is to say at an angle that is greater than 90°.

In a further embodiment, the insertion component is rod-shaped and the at least one guide channel extends from an end face of the insertion component to a lateral surface of the insertion component. In this case, the cavity in the workpiece typically is a straight-lined channel, which preferably has a constant diameter and which extends into the volume of the workpiece starting from an opening on a side of the workpiece. In this case, the insertion component is inserted into the cavity by virtue of the latter being pushed into the cavity through the opening in the workpiece. In this case, the end face of the insertion component is accessible from the outside through the opening in the workpiece, and so the flexible fluid lines are able to be led away from the workpiece at the end face of the insertion component and are able to be connected to a provision device for the fluid, which comprises a pump or the like. With the aid of the above-described rounded-off section of the guide channel, a respective flexible fluid line can be guided from the end face of the insertion component to the lateral surface of the insertion component.

In a development of this embodiment, the guide channels merge into openings at the lateral side of the insertion component, the said openings preferably being arranged next to one another in the longitudinal direction of the insertion component and being in particular arranged at equal distances in relation to one another in the longitudinal direction of the insertion component. An arrangement of the openings next to one another in the longitudinal direction of the insertion component is understood to mean that the openings extend along a common straight line or line running in the longitudinal direction of the insertion component. Expressed differently, the openings are not offset from one another in the circumferential direction of the insertion component. This is advantageous if a plurality of structures that branch off from the cavity along a common line are intended to be produced by multi-photon laser ablation. If the structures to be formed are arranged at equal distances from one another, the openings are also arranged equidistantly, that is to say at the same distances from one another, in the longitudinal direction of the insertion component.

In a development of this embodiment, the rod-shaped insertion component has a circular cylindrical form and preferably has a diameter of between 5 mm and 10 mm. The geometry of the insertion component is adapted to match the geometry of the cavity, which likewise has a circular cylindrical form in this case. The diameter of the cavity is slightly larger than the diameter of the insertion component. A cylindrical cavity which has a comparatively large diameter can be produced by mechanical processing, for example by grinding, and maybe in the form of a blind hole, for example. In this case, the insertion component is typically pushed into the cylindrical cavity until it rests against the end face of the cavity. The position of the openings in the longitudinal direction of the insertion component is defined in this way. The insertion component is additionally aligned or rotated such that the openings in the lateral surface of the insertion component are positioned in the circumferential direction such that these openings correspond to the points from which the structures which branch off the cavity should start. Moreover, the end face of the insertion component may have a protruding section, that is to say a tongue, which latches in a notch or groove in the workpiece in order to simplify axial positioning; this corresponds to the key-lock principle. A spacer, for example in the form of a solid cylinder, may be introduced into the cavity prior to the insertion of the insertion component, the insertion component being brought into contact with the end face of the said spacer. The length of the insertion component can be reduced thereby.

In a further embodiment, the at least one guide channel has an internal diameter of between 1 mm and 4 mm. The structures emanating from the cavity generally have a significantly smaller diameter than the insertion component. This is advantageous since this allows a plurality of guide channels, which extend within the insertion component, to be accommodated in the insertion component.

In a further embodiment, the at least one fluid line has an external diameter of 1 mm or less. As described above, it is generally necessary for a gap for the return of the fluid to remain between the fluid line and the wall of a respective guide channel. The external diameter of the fluid line is therefore correspondingly smaller than the internal diameter of the guide channel.

The insertion component may be formed in various ways. By way of example, the guide channels can be formed as pipes, for example as stainless steel pipes or as plastic pipes, which are or have been bent in order to form the rounded-off section or sections. The guide channels in the form of the pipes, for example the stainless steel pipes or the plastic pipes, can be bundled together and, for example, can be moulded into a suitable material in order to produce an insertion component with a desired geometry, for example in the style of a cylinder.

Alternatively, the insertion component may be produced by an additive manufacturing method. In this case, the insertion component typically consists of a body produced using the 3-D printing method, in which the guide channels in the form of hollow structures are formed during additive manufacturing. For the production of the insertion component, use can be made of the metals, plastics or even glass-like materials that are typical for 3-D printing.

In a further embodiment, the fluid feed apparatus comprises a fluid provision device for feeding the fluid to the at least one flexible fluid line. The fluid provision device may comprise a fluid reservoir for providing the fluid. As described above, it is typically advantageous to let the fluid emerge from the fluid line at a comparatively high pressure. It is therefore advantageous to feed the fluid to the flexible fluid line with the aid of a pump which generates a correspondingly high pressure and which is a part of the fluid provision device.

In a further embodiment, the fluid feed apparatus comprises at least one tracking device for automated tracking by the at least one flexible fluid line of a movement of the removal front in the material of the workpiece. In the case of the multi-photon laser ablation, the removal front typically moves at a constant processing speed within the volume of the workpiece. The automated tracking by the flexible fluid line is likewise implemented at the processing speed. For tracking purposes, the flexible fluid line is advanced, for example by virtue of the latter being unwound from a coil or the like at a constant speed. For tracking by the flexible fluid line, it is generally necessary for the material of the fluid line to have a sufficient shear rigidity, but this is typically the case for the materials used for flexible fluid lines. In the case where the removal fronts move within the material of the workpiece at different processing speeds, the tracking device may be designed to allow the fluid lines to track at an individually adapted speed.

A further aspect of the invention relates to a method for feeding a fluid with a fluid feed apparatus designed as described above to at least one removal front when removing material from a workpiece through multi-photon laser ablation, preferably from an in particular monolithic substrate for an EUV mirror, the method comprising: inserting the insertion component into a cavity of the workpiece and feeding the fluid to the at least one removal front through the at least one flexible fluid line, which is guided in the at least one guide channel of the insertion component. As described above, a fluid feed apparatus designed as described above allows the flexible fluid line to track, in an automated manner, the removal front when the latter moves through the workpiece.

In a variant, the cavity is filled with a fluid prior to the insertion of the insertion component and a plurality of channel sections adjacent to the cavity are formed by multi-photon laser ablation starting from the cavity that is filled with the fluid. For the production of comparatively short sections of channels or other structures that start or branch off from the cavity, a local feed of a fluid to the removal front with the aid of the flexible fluid line is typically not required: In the case of a length of the channel section which is generally of the order of no more than approx. 20-40 mm, it is sufficient if the cavity as a whole—and hence also the channel sections formed during the multi-photon absorption—are filled with fluid. Typically, the workpiece with the fluid is partially immersed in a liquid or in a liquid bath, usually in a water bath, for this purpose.

In a development of this variant, a plurality of removal fronts are generated starting from the end faces of the channel sections following the insertion of the insertion component into the cavity and are moved in the material of the workpiece in order to produce a plurality of channels, with the plurality of the flexible fluid lines tracking the movement of the removal fronts in the material of the workpiece.

Should the workpiece be a substrate for an EUV mirror, the said workpiece may for example have two cavities, which serve as fluid distributor and fluid collector and into each of which an insertion component is inserted. The two cavities are fluidically interconnected by a plurality of channels, which branch off the first cavity and open into the second cavity. Proceeding from in each case one of the two cavities, it is possible in this case to in each case produce a first or second channel section, which corresponds to approximately half the length of a respective channel, through multi-photon laser ablation. Approximately in the middle of the length of the channel there is an overlap of the removal fronts of the two channel sections during the production, as a result of which a continuous channel arises, the latter connecting the fluid distributor to the fluid collector.

Should the channels be cooling channels or cooling structures for an EUV mirror, these typically do not extend in a straight line between the fluid distributor and the fluid collector and instead are angled and generally have a distributor channel in which the fluid is transported to the vicinity of the surface starting from the fluid distributor, which has a comparatively large distance from the optical surface of the EUV mirror. The fluid, typically in the form of cooling water, is guided along the surface in a channel section that forms a cooling channel before the fluid is removed from the surface in a collector channel and fed to the fluid connector.

Further features and advantages of the invention will be apparent from the description of working examples of the invention that follows, with reference to the figures of the drawing, which show details associated with the invention, and from the claims. The individual features can each be implemented alone or in a plurality in any combination in one variant of the invention.

### BRIEF DESCRIPTION OF THE DRAWINGS

Exemplary embodiments are depicted in the schematic drawing and are explained in the following description. In detail:

FIG. 1 shows a schematic of a meridional section of a projection exposure apparatus for EUV projection lithography,

FIGS. 2A and 2B show schematic representations of EUV mirrors with a substrate, into which a hollow structure in the form of a cooling channel is introduced,

FIG. 3 shows a schematic representation of an apparatus for producing the hollow structure of FIG. 2A through material-removing processing of the substrate with pulsed laser radiation when forming an undercut,

4 FIGS. 4A-4C show a schematic representation of a plan view and a side view of a movement pattern with mutually offset trajectories in the incoming radiation direction of the pulsed laser radiation at the substrate, and the generation of an obliquely aligned removal front with the aid of the apparatus of FIG. 3,

FIG. 5A shows a schematic representation of a plan view of a movement pattern with mutually offset trajectories which are generated when focusing the pulsed laser radiation with different pulse energies,

FIG. 5B shows a schematic sectional representation of the substrate with an oblique removal front which is generated when focusing the pulsed laser radiation into a focal plane using the ablation pattern with different pulse energies shown in FIG. 5A,

FIGS. 6A-6C show schematic representations analogous to FIG. 3 during three different phases of the production of the hollow structure and with a fluid feed comprising a nozzle or a flexible tubing,

FIGS. 7A-7C show two process steps during the production of a hollow structure in the form of a continuous cooling channel and of a seam region formed in the process,

FIGS. 8A and 8B show schematic sectional representations of a mirror of the projection exposure apparatus of FIG. 1, having a hollow structure with a plurality of temperature control channels in the form of cooling channels, the end sections of which merge into distributor channels or into collector channels via rounded-off sections,

FIGS. 9A-9D show schematic representations of a rounded-off section between a distributor channel and an end section of a cooling channel with in each case an identical flow diameter for four different radii of curvature,

FIGS. 10A-10D show schematic representations of a rounded-off section between a collector channel and an end section of a cooling channel with in each case an identical flow diameter for four different radii of curvature,

FIG. 11A shows a perspective representation of a substrate for an EUV mirror with a hollow structure analogous to FIGS. 8A and 8B, in which the end sections of the cooling channels are aligned at an obtuse angle with respect to the distributor channels or the collector channels,

FIG. 11B shows a schematic representation of a rounded-off section at the transition between an end section of a cooling channel and a distributor channel,

FIGS. 12A-12D show representations of the substrate for an EUV mirror with a hollow structure analogous to FIGS. 8A and 8B, in which the distributor channels and the collector channels are aligned at an obtuse angle with respect to an inlet channel and an outlet channel, respectively, and merge into the inlet channel or the outlet channel at a rounded-off section,

FIGS. 13A and 13B show schematic sectional representations of a mirror of the projection exposure apparatus of FIG. 1 with a hollow structure having a plurality of cooling channels,

FIG. 13C shows a schematic representation of the mirror of FIGS. 13A and 13B during the production of the hollow structure using a fluid feed apparatus with two different insertion components,

FIGS. 14A-14C show schematic representations of a first example of the fluid feed apparatus with an insertion component having a plurality of guide channels in the form of bent pipes for guiding flexible fluid lines, and

FIGS. 15A and 15B show schematic representations of the second example of the fluid feed device, in which the insertion component was produced by additive manufacturing.

### DETAILED DESCRIPTION

In the following description of the drawings, identical reference signs are used for identical or analogous or functionally identical or analogous components.

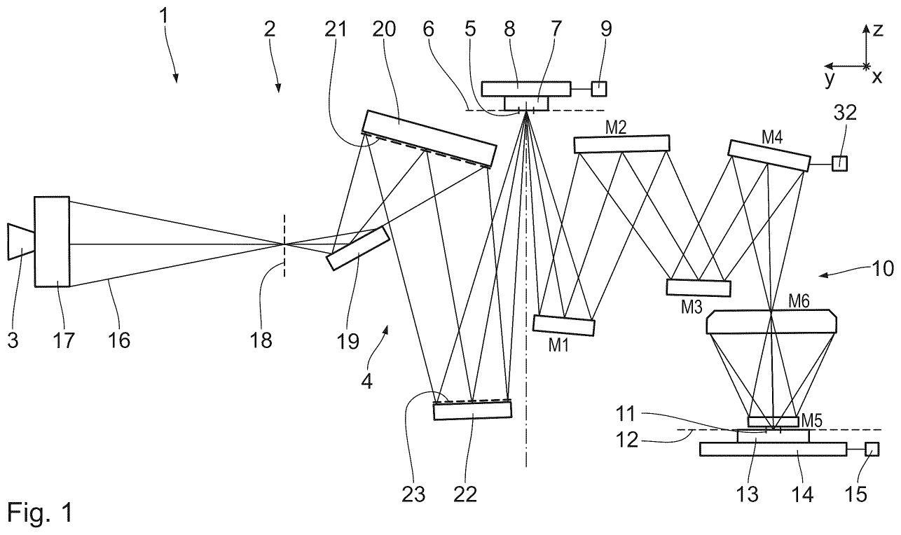

The salient components of an optical arrangement for EUV lithography in the form of a microlithographic projection exposure apparatus 1 are described by way of example below with reference to FIG. 1. The description of the basic set-up of the projection exposure apparatus 1 and the components thereof should not be understood as limiting in this case.

An embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable through a reticle displacement drive 9, in particular in a scanning direction.

For purposes of explanation, a Cartesian xyz coordinate system is depicted in FIG. 1. The x-direction runs perpendicular to the plane of the drawing into the latter. The y-direction runs horizontally and the z-direction runs vertically. The scanning direction runs along the y-direction in FIG. 1. The z-direction runs perpendicularly to the object plane 6.

The projection exposure apparatus 1 comprises a projection system 10. The projection system 10 serves for imaging the object field 5 into an image field 11 in an image plane 12. A structure on the reticle 7 is imaged onto a light-sensitive layer of a wafer 13 arranged in the region of the image field 11 in the image plane 12. The wafer 13 is held by a wafer holder 14. The wafer holder 14 is displaceable through a wafer displacement drive 15 in particular along the y-direction. The displacement, firstly, of the reticle 7 through the reticle displacement drive 9 and, secondly, of the wafer 13 through the wafer displacement drive 15 can be implemented so as to be synchronized with one another.

The radiation source 3 is an EUV radiation source. The radiation source 3 emits, in particular, EUV radiation 16, which is also referred to below as used radiation, illumination radiation or illumination light. In particular, the used radiation has a wavelength in the range of between 5 nm and 30 nm. The radiation source 3 can be a plasma source, for example an LPP source, that is to say a laser produced plasma source, or a DPP source, that is to say a gas discharge produced plasma source. It may also be a synchrotron-based radiation source. The radiation source 3 can be a free electron laser, which is also referred to by the acronym FEL.

The illumination radiation 16 emanating from the radiation source 3 is focused by a collector mirror 17. The collector mirror 17 can be a collector mirror with one or more ellipsoidal and/or hyperboloidal reflection surfaces. The at least one reflection surface of the collector mirror 17 can be impinged on by the illumination radiation 16 with grazing incidence (GI), that is to say at angles of incidence of greater than 45°, or with normal incidence (NI), that is to say at angles of incidence of less than 45°. The collector mirror 17 can be structured and/or coated, firstly, for optimizing its reflectivity for the used radiation and, secondly, for suppressing extraneous light.

The illumination radiation 16 propagates through an intermediate focus in an intermediate focal plane 18 downstream of the collector mirror 17. The intermediate focal plane 18 can represent a separation between a radiation source module, having the radiation source 3 and the collector mirror 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect that goes beyond the purely deflecting effect. Alternatively or in addition, the deflection mirror 19 may be in the form of a spectral filter that separates a used light wavelength of the illumination radiation 16 from extraneous light of a wavelength deviating therefrom. The first facet mirror 20 comprises a multiplicity of individual first facets 21, which are also referred to as field facets below. FIG. 1 depicts only some of said facets 21 by way of example. In the beam path of the illumination optical unit 4, a second facet mirror 22 is arranged downstream of the first facet mirror 20. The second facet mirror 22 comprises a plurality of second facets 23.

The illumination optical unit 4 consequently forms a doubly faceted system. This fundamental principle is also referred to as a fly's eye condenser (fly's eye integrator). With the aid of the second facet mirror 22, the individual first facets 21 are imaged into the object field 5. The second facet mirror 22 is the last beam-shaping mirror or actually the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example depicted in FIG. 1, the projection system 10 comprises six mirrors M1 to M6. Alternatives with four, eight, ten, twelve or any other number of mirrors Mi are likewise possible. The penultimate mirror M5 and the last mirror M6 each have a through opening for the illumination radiation 16. The projection system 10 is a doubly obscured optical unit. The projection optical unit 10 has an image-side numerical aperture that is greater than 0.4 or 0.5 and can also be greater than 0.6, and can be for example 0.7 or 0.75.

Just like the mirrors of the illumination optical unit 4, the mirrors Mi can have a highly reflective coating for the illumination radiation 16.

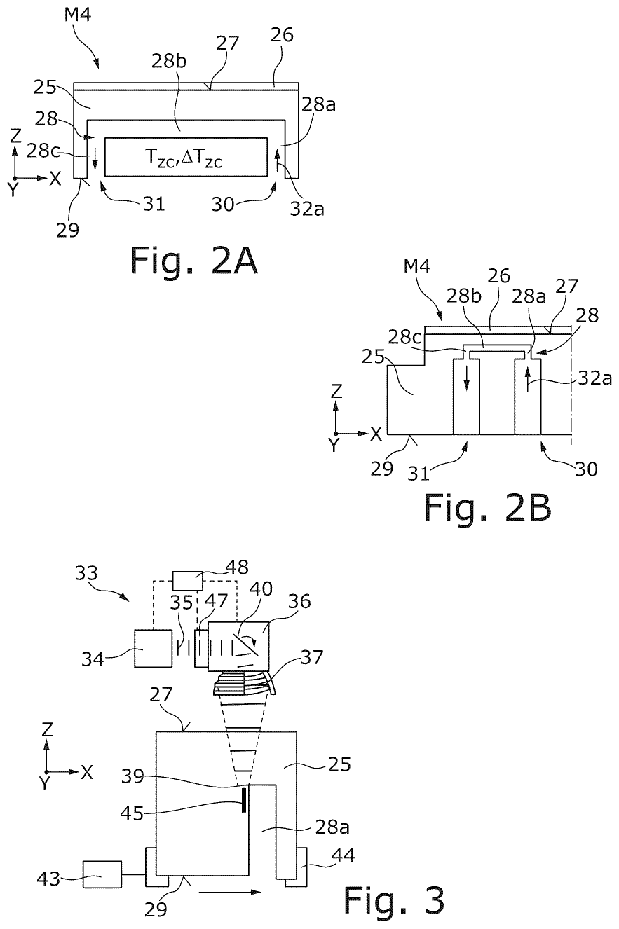

FIGS. 2A and 2B show, in exemplary fashion, a mirror M4 of the projection system 10, the said mirror comprising a substrate 25 which has a surface 27 to which a reflective coating 26 is applied. In the example shown, the material of the substrate 25 is titanium-doped fused silica with a very small coefficient of thermal expansion. The substrate 25 may also be formed from a different material with a coefficient of thermal expansion that is as small as possible, for example a glass ceramic. These materials are zero-expansion materials, which pit components or phases with positive and negative coefficients of thermal expansion against one another. These materials have exactly one temperature value for which the thermal expansion vanishes or is the least sensitive to changes in the temperature; to be precise, this is what is known as the zero-crossing temperature T_{ZC}, which is also referred to as ZCT. In the example described here, the material of the substrate 25, titanium-doped fused silica with a very small coefficient of thermal expansion, has a zero-crossing temperature T_{ZC} which is between 0° C. and 100° C., typically between 19° C. and 40° C., in particular between 19° C. and 32° C. The zero-crossing temperature T_{ZC} is substantially constant throughout the volume of the substrate 25 and has a spatial variation that is less than 3 K, less than 2 K, less than 1 K or less than 0.1 K, with the spatial variation denoting the difference between maximum and minimum zero-crossing temperature T_{ZC}.

In the example shown, the substrate 25 has a monolithic form. In the example shown, the reflective coating 26 has a plurality of layer pairs made of materials with different real parts of the refractive index, the layers possibly being formed from Si and Mo, for example, in the case of a wavelength of the EUV radiation 16 of 13.5 nm. The surface 27 of the substrate 25 is represented as a plane area in FIGS. 2A and 2B, although it may also have a curvature.

In the example shown in FIGS. 2A and 2B, the substrate 25 has a continuous hollow structure 28 in the form of a channel, through which a coolant, indicated by an arrow, in the form of a temperature control fluid, a cooling fluid 32a in the present case, is able to flow, the temperature control fluid being water in the example described here. Therefore, the hollow structure 28 is sometimes also referred to as cooling channel below. It is understood that a heating fluid is also able to flow through the hollow structure 28, for the purposes of heating the substrate 25. The cooling channel 28 has a first section 28a which extends in the vertical direction, that is to say in the Z-direction of an XYZ-coordinate system, starting from a coolant inlet 30 formed on a back side 29 of the substrate 25. The vertical direction Z corresponds to the thickness direction Z of the substrate 25. In the example described here, the top side 27 and the lower side 29 of the substrate 25 are each aligned perpendicular to the thickness direction Z.

The first, vertical section 28a of the cooling channel 28 is adjoined by a section 28b which extends horizontally, that is to say in the X-direction, and through which the coolant 33 flows into a third section 28c of the cooling channel 28 which extends vertically and which opens into a coolant outlet 31 on the back side 29 of the substrate 25. With the exception of the two transitions between the respective vertical section 28a, 28c and the horizontal section 28b, the hollow structure 28 in the form of the cooling channel shown in FIG. 2A has a round cross section with a constant diameter, which is of the order of approx. 1-5 mm in the example shown. The continuous cooling channel 28 shown in FIG. 2B differs from the continuous cooling channel 28 shown in FIG. 2A in that a part in each of the vertical sections 28a,c, which start from the coolant inlet 30 and from the coolant outlet 31, respectively, has a larger diameter than the horizontal section 28b and a short part of the vertical sections 28a,c, which is respectively situated at the transition to the horizontal section 28c of the cooling channel 28.

To feed the coolant 32a to the coolant inlet 30 and to remove the coolant 32a from the coolant outlet 31, the projection exposure apparatus 1 comprises a cooling device 32, which is represented schematically in FIG. 1. In the example shown, the cooling device 32 serves to feed a coolant 32a in the form of cooling water to the cooling channel 28 or to the mirror M4, and to this end comprises a feed line, not depicted here, which is connected to the coolant inlet 30 in fluid-tight fashion. The cooling device 32 also comprises a removal line, not depicted here, in order to remove the cooling water 32a from the coolant outlet 31. The other mirrors M1-M3, M5, M6 of the projection system 10 may also have a hollow structure 28 which, for cooling purposes, is connected to the cooling device 32 or optionally to further cooling devices provided to this end. It is understood that, in principle, any mirror may have a hollow structure 28 through which a coolant is able to flow. By way of example, this may relate to mirrors designed to reflect radiation in the DUV/VUV wavelength range, in the visible wavelength range and/or in the infrared wavelength range. Instead of a cooling device 32, a temperature control device may also be provided in the projection exposure apparatus 1, that is to say a device used to cool and/or heat the mirrors M1-M6. A suitable temperature control fluid 32a can be used for heating, for example water which is heated to a desired temperature before being fed to the hollow structure 28.

An apparatus 33, which is represented schematically in FIG. 3, serves to produce the cooling channel 28 shown in FIG. 2A. The apparatus 33 comprises a laser source 34 that serves to produce pulsed laser radiation 35, which is represented in the form of dashes in FIG. 3. The laser source 34 is an ultrashort pulse laser source designed to produce laser pulses with pulse durations of the order of picoseconds, for example of less than 10 ps, with peak pulse powers in the MW range. The laser source 34 is designed to produce the pulsed laser radiation 35 with a wavelength in the near infrared wavelength range, more precisely at 1030 nm. However, it is also possible that the laser source 34 is designed to produce the pulsed laser radiation 35 with a wavelength in the visible wavelength range or another wavelength in the near infrared wavelength range for which the material of the substrate 25 is transparent.

The apparatus 33 also comprises a scanner optical unit 36 and a focusing device 37. In the example shown, the focusing device 37 is designed as an F-theta lens and serves to focus the pulsed laser radiation in the form of a pulsed laser beam into a focal region 39 within the substrate 25. The scanner optical unit 36 serves to radiate the pulsed laser radiation 35 on a beam entrance side 27 of the substrate 25 in an incoming radiation direction Z, which is aligned perpendicular to the beam entrance side 27, and to move the focal region 39 within the substrate 25, the said scanner optical unit comprising, to this end, a galvanometer mirror 40 that is tiltable in two directions. Instead of one galvanometer mirror 40, it is also possible that two galvanometer mirrors, each tiltable in one direction, are arranged within the scanner optical unit 36. It is also possible to use other types of mirrors, for example piezoelectric mirrors, in place of the galvanometer mirrors.

As described above, the focal region 39 can be moved within the substrate 25 by tilting the mirror 40. As a result of the F-theta lens 37, which corrects a field curvature in the case of different alignments of the galvanometer mirror 40, the focal region 39 is moved in an XY-plane perpendicular to the incoming radiation direction Z when the mirror 40 is tilted. The incoming radiation direction Z of the pulsed laser radiation 35 at the substrate 25 therefore substantially corresponds to the thickness direction Z of the substrate 25.

With the aid of the scanner optical unit 36, the focal region 39 is moved along an ablation pattern 41, which is shown in FIG. 4A in a plan view. The ablation pattern 41 has a plurality of straight-line trajectories 42, which are aligned in parallel, extend in the Y-direction and, in the example shown, are arranged at equal distances from one another in the X-direction. It is not mandatory for the trajectories 42 to be arranged at the same distances from one another; rather, the distances between adjacent trajectories 42 may also vary in process-dependent fashion within the ablation pattern 41.

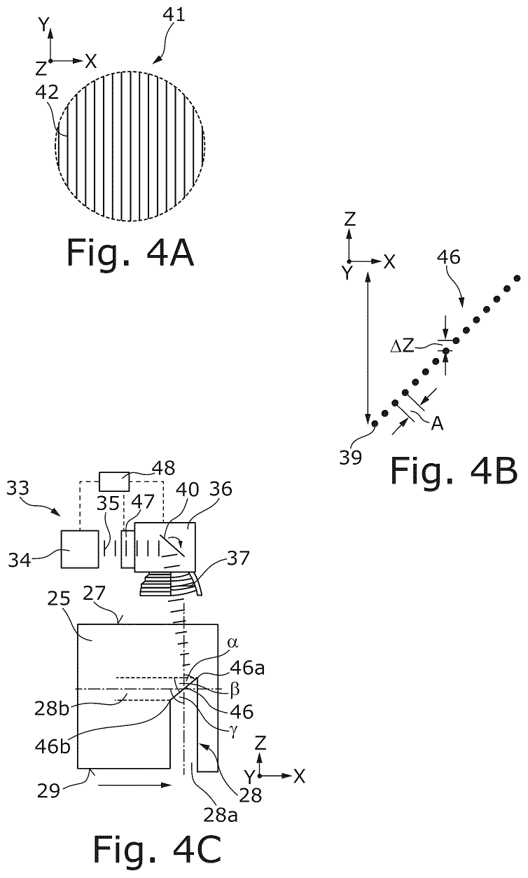

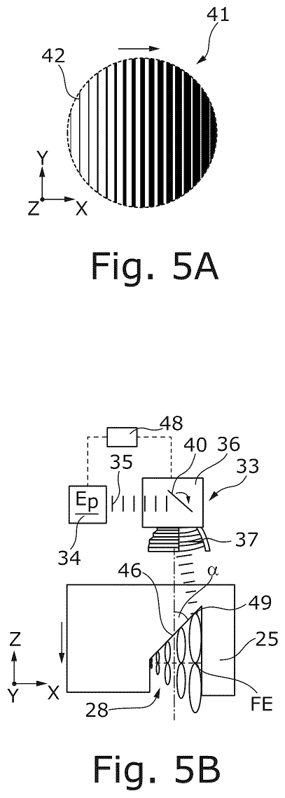

To produce the vertical section 28a of the cooling channel shown in FIG. 3, the ablation pattern 41 shown in FIG. 4A is generated in an XY-plane on the back side 29 of the uncoated substrate 25 with the aid of the scanner optical unit 36. With the aid of a positioning device 43 which is represented very schematically in FIG. 3 and which acts on a holder 44 for the substrate 25, the substrate 25 is displaced downward in the incoming radiation direction Z of the pulsed laser radiation 35 at the beam entrance side 27 of the substrate 25 while the scanner optical unit 36 generates the ablation pattern 41, shown in FIG. 5A, multiple times. The vertical section 28a of the cooling channel 28 shown in FIG. 3 is formed hereby, starting from the back side 29 of the substrate 25.

FIG. 3 shows the production process of the hollow structure 28 when producing a transition in the form of an undercut with an undercut angle of 90° between the vertical section 28a of the cooling channel 28 and the horizontal section 28b of the cooling channel 28. If, in the process, the pulsed laser radiation 35 is laterally guided along the upper end of the vertical section 28a, as indicated in FIG. 3, in order to remove material for the production of the horizontal section, this leads to an interaction of the pulsed laser radiation 35 with the material of the substrate 25 therebelow and this interaction induces modifications and stress in the material of the substrate 25, as indicated in FIG. 3 by a solid vertical line 45.

This problem is rectified by virtue of generating a removal front 46 which is not aligned perpendicular to the incoming radiation direction Z; cf. FIG. 4C. In the example shown in FIG. 4C, the removal front 46 has an angle α of 45° with respect to the incoming radiation direction Z. However, the angle α with respect to the incoming radiation direction Z may also be larger or smaller and may for example be aligned with respect to the incoming radiation direction Z in a value range between 0° and 89°, 10° and 80°, 20° and 70° or between 30° and 60°.

In FIG. 4C, the removal front 46 is tilted in the direction toward the radiation entrance side 27 of the substrate 25 in order to produce the horizontal section 28b of the cooling channel 28, which is indicated using dashed lines in the representation of FIG. 4C on account of not yet having been produced. To produce the horizontal section 28b of the cooling channel 28 and as indicated in FIG. 4C by an arrow, the substrate 25 is displaced in the X-direction with the aid of the positioning device 43 in order to continuously ablate material along the removal front 46. As is likewise apparent from FIG. 4C, the upper edge 46a of the removal front 46 that is closer to the radiation entrance side 27 of the substrate 25, when the said removal front is moving in the horizontal X-direction, is aligned at an angle β of 45° with respect to the movement direction of the removal front 46 within the substrate 25 corresponding to the negative X-direction. A lower edge 46b of the removal front 46 that is distant from the radiation entrance face 27 projects further in the movement direction than the upper edge 46a of the removal front 46 when the horizontal section 28b of the hollow structure 28 is produced. As a result, only the lower edge 46b of the removal front 46 is adjacent to the material of the substrate 25, and so the interaction of the pulsed laser radiation 35 with the material of the substrate 25 can be reduced to a minimum during the production of the horizontal section 28b. As is likewise apparent from FIG. 4C, the first re-emergence of the pulsed laser radiation 35 from the material of the workpiece 25 following the entrance at the radiation entrance face 27 is in the region of the removal front 46.

In the example shown in FIG. 4C, the tilted removal front 46 is generated by virtue of the focal range 39 being offset in each case by a value Δz, constant in the example shown, between two neighboring trajectories 42 in the incoming radiation direction Z, as illustrated in FIG. 4B. A distance A between neighboring trajectories 42 along the removal front 46 that has been tilted through 45° with respect to the incoming radiation direction Z is between approx. 0.01 mm and 0.5 mm, for example approx. 0.03 mm, in the example shown. In order to be able to quickly offset the focal region 39 in the incoming radiation direction Z between the traversal of neighboring trajectories 42, the apparatus 33 comprises a focus offset device 47, which is in the form of a dynamic zoom lens. The focus offset device 47 is controlled with a control device 48 for generating the offset in the incoming radiation direction Z. The control device 48 also serves to control the laser source 34 and the scanner device 36, in order to synchronize the offset in the incoming radiation direction Z with the movement of the focal region 39 along the respective trajectory 42. In the example shown, the diameter of the circular cross section of the cooling channel 28 in the example shown is approx. 2 mm.

FIGS. 5A and 5B show a further option for forming an oblique removal front 46, which is likewise aligned at an angle α of 45° with respect to the incoming radiation direction Z. As is apparent from FIG. 5B, the apparatus 33 for producing the hollow structure 28 does not have a focus offset device. In the apparatus 33 shown in FIG. 5B, the pulsed laser radiation 35 is focused onto a focal plane FE which is aligned perpendicular to the incoming radiation direction Z. As is apparent from FIG. 5A, the pulse energy E_{P} of the pulsed laser radiation 35 is increased incrementally between neighboring trajectories 42 or the corresponding scan lines in the focal plane FE in order to form the removal front 46, as indicated in FIG. 5A by an increase in the line thickness of the trajectories 42.

The control device 48 acts on the laser source 34 in order to increase the pulse energy E_{P}. The laser source 34 comprises a device for adjusting the pulse energy E_{P}, which device may be in the form of an acousto-optic modulator or electro-optic modulator, for example. Such modulators have response times of the order of microseconds or less and enable a quick increase in the pulse energy E_{P} between in each case two neighboring trajectories 42 of the ablation pattern 41. As is apparent from FIG. 5B, the range of influence of the pulsed laser radiation 35 on the material of the substrate 25 depends on the pulse energy E_{P}, in addition to other parameters. Depending on specified parameters such as the wavelength of the pulsed laser radiation 35 and the pulse duration of the pulsed laser radiation 35, a certain threshold energy density or intensity is required to ablate the material of the substrate 25. The greater the pulse energy E_{P}, the greater the extent of the region, starting from the focal plane FE, where material removal may occur.

FIG. 5B shows the extent of the iso-lines of the energy density within the substrate 25 with a boundary 49 in the incoming radiation direction Z where removal may still occur. As a result of the incremental increase of the pulse energy E_{P} in the X-direction, as indicated by an arrow in FIG. 5A, it is possible to displace the boundary 49 in the incoming radiation direction Z and to form the removal front 49 shown in FIG. 5B, which is aligned at an angle of 45° with respect to the incoming radiation direction Z. Consequently, an oblique removal front 46 can be formed in the manner described in conjunction with FIGS. 5A and 5B, without the apparatus 33 having additional movable elements such as a focus offset device 47 to this end. As described in the context of FIG. 3, the vertical section 28a of the channel 28 may also be produced by a downward movement of the substrate 25 in the Z-direction in this case, as indicated in FIG. 5B by an arrow.

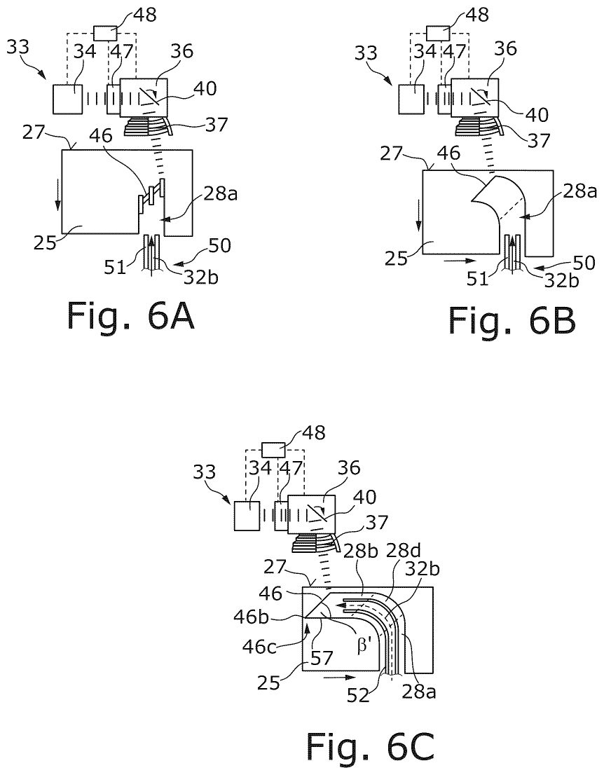

FIGS. 6A-6C show three phases of the production of an angled hollow structure 28 which has a vertical section 28a and a horizontal section 28b, which merge into one another at a rounded-off section 28d or at a curve. In this case, the apparatus 33 for producing the hollow structure 28 is designed like in FIGS. 4A-4C, that is to say it comprises a focus offset device 47 to form the oblique removal front 46. As is apparent from FIG. 6A, the vertical channel section 28a is produced in a first phase by virtue of the substrate 25 being displaced downward, as a result of which the removal front 46 is moved within the substrate 25 and material of the substrate 25 is ablated continuously, while the scanner optical unit 36 remains stationary. Since all that matters for the material removal is the relative movement between the removal front 46 and the substrate 25, the substrate 25 may remain stationary in the incoming radiation direction Z and the scanner optical unit 36 may be moved upward for moving the removal front 46 within the substrate 25 in alternative fashion. In principle, a superposed movement of the substrate 25 and the scanner optical unit 36 in the Z-direction is also possible.

The removed material is removed from the removal front 46 with the aid of a fluid feed 50. In the example shown, the fluid feed 50 comprises a stationary nozzle 51, from which a liquid, water 32b in the example shown, emerges, the liquid emanating in the vertical direction and being fed to the removal front 46. The alignment of the nozzle 51 upwards in the vertical direction enables a targeted removal of the removal particles from the removal front 46, which are removed through the gap between the nozzle 51 and the wall of the vertical section 28a of the hollow structure 28 on account of the action of gravity. The removal front 46 thereby remains substantially free from depositions and the removal can be implemented without interruptions. Simultaneously, feed of the liquid 32b allows active cooling of the removal front 46 or the processing zone, as a result of which the residual heat in the substrate 25 is reduced. As an alternative to feeding a liquid 32b, a gas, for example compressed air, can also be fed to the removal front 46 with the aid of the fluid feed 50.

FIG. 6B shows a phase during the production of the hollow structure 28 in which the rounded-off section 28d of the hollow structure 28 is formed, the said rounded-off section forming a 90° transition between the vertical section 28a and the horizontal section 28b of the hollow structure 28. When the rounded-off section 28d is formed, the substrate 25 is also displaced in the X-direction in addition to the displacement in the Z-direction, as indicated by an arrow, while the removal front 46 inclined at 45° is still formed in the manner described above.

The rounded-off section 28d allows the introduction of a flexible tubing 52 into the hollow structure 28, the removal front 46 being tracked by the said flexible tubing during the production of the horizontal section 28b of the hollow structure 28, as illustrated in FIG. 6C. As a result, the removal products can be effectively removed from the removal front 46, even during the production of the horizontal section 28b. As a result of continuous tracking by the tubing 52, the attainable length of the hollow structure 28 is limited only by the size of the substrate 25 and the length of the tubing 52.

The above-described tilt of the removal front 46 need not necessarily be undertaken when producing a hollow structure, for example in the form of a straight-lined channel, by material-removing processing with pulsed laser radiation 35. Even in the case where the intention is to produce a hollow structure in the form of a channel 28 with a comparatively long length extending in a straight line, it is necessary to at least partially introduce the fluid feed 50 or a part of the fluid feed 50 into the channel 28 in order to feed the rinsing fluid 32b to the removal front 46. To this end, the fluid feed 50 may for example comprise a rigid pipe or the like, which is at least partially introduced into the channel 28. Especially for the case that a curved channel 28 should be formed, the fluid feed 50 may comprise a flexible element, for example in the form of a flexible tubing 52, which is at least partially introduced into the channel 28 in order for the removal front 46 to be tracked by the free end of the said flexible element. A nozzle may be attached to the free end of the tubing 52, but this is not mandatory.

As is likewise evident from FIG. 6C, material of the substrate 25 during the production of the horizontal section 28b of the hollow structure 28 is adjacent to a side 46c of the edge 46b of the removal front 46 that is distant from the radiation entrance side 27 of the substrate 25, the said side being distant from the radiation entrance side 27 of the workpiece 25, that is to say material of the substrate 25 is situated below the lower edge 46b of the removal front 46 in FIG. 6C. Additionally, when producing the horizontal section 28b of the hollow structure 28, some of the laser radiation 35 emerging from the region of the removal front 46 or emanating into the hollow structure 28 from the removal front 46 re-enters the material of the substrate 25, to be precise at the lower edge of the lateral surface of the hollow structure in the form of the channel 28 in FIG. 6C.

As is likewise apparent from FIG. 6C, the removal front 46 includes an angle β′ with a lateral surface 57 of the channel 28 which is cylindrical in the example shown, the angle also being referred to as removal front angle below. During the production of the channel 28, the removal front angle β′ is typically at least intermittently greater than a removal front minimum angle of 1°, 5°, 10°, 20° or 30° and at least intermittently less than a removal front maximum angle of 89°, 85°, 80°, 70° or 60°. The removal front angle β′ during the production of the channel 28 may be permanently greater than the removal front minimum angle and/or permanently less than the removal front maximum angle, but this is not mandatory.

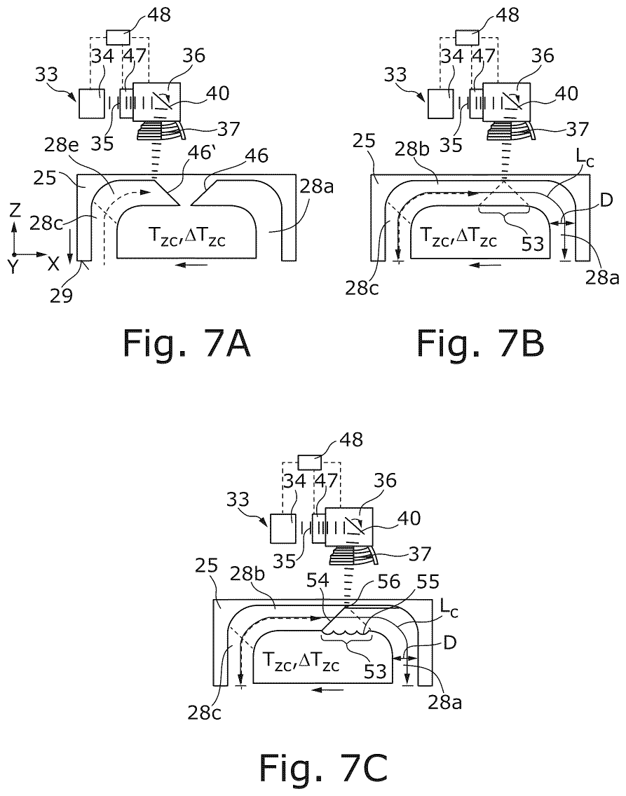

FIGS. 7A and 7B show two further phases or steps during the production of the hollow structure 28, which follow the phases described in conjunction with FIGS. 6A-6C. As is apparent from FIG. 7A, a further vertical section 28c of the hollow structure 28, which is followed by a further rounded-off section 28c, is produced starting from the back side 29 of the substrate 25 in a manner corresponding to the phase shown in FIG. 6A. In the phase of the production of the hollow structure 28 shown in FIG. 7A, the alignment of the removal front 46 is mirrored in comparison with FIG. 6A, and the substrate is displaced in the negative X-direction in order to form the horizontal section 28b. As is apparent from FIG. 7B, the mirrored removal front 46′ is displaced in the horizontal direction by the continuous processing until the said mirrored removal front reaches the already processed part of the horizontal section 28b of the hollow structure 28 such that a continuous horizontal section 28b is produced and the hollow structure 28 in the form of the channel is opened to be continuous.

A seam region 53 arises when opening the channel 28 to be continuous, the said scam region extending in the region of the two adjoining dashed lines in FIG. 7B that correspond to the respective last removal front 46, 46′ formed during the production of a respective part of the channel 28. The nature of the channel 28, more precisely the nature of the wall of the channel 28, in the seam region 53 differs from the nature of the wall of the channel 28 outside of the seam region in terms of at least one property, or the seam region 53 has at least one structural modification vis-à-vis the remaining channel 28.

FIG. 7C shows three examples of such structural modifications: In the example shown in FIG. 7C, a surface structure of the wall of the channel 28 in the seam region 53 firstly differs from a surface structure of the wall of the channel 28 outside of the seam region 53 in that the edge contour 54 of a removal front 46 is observable on the surface structure in the scam region 53. The edge contour of the other removal front 46′ is also partly written into the surface structure of the channel 28 in the seam region 53, but this is not depicted in FIG. 7C. The edge contour 54 of the removal front 46 extends in ellipsoidal fashion in the example shown and is aligned at an angle of approx. 45° with respect to the lateral surface of the channel 28, that is to say at the same angle as the removal front 46 itself (cf. FIG. 6C).

In the example shown in FIG. 7C, four bulges 55 are moreover formed on the wall of the channel 28 in the seam region 53, the bulges each locally increasing the cross section of the channel 28. Bulges that reduce the cross section of the channel 28 are likewise possible. Additionally, the wall of the channel 28 has a minor lateral offset 56 in the style of a step in the seam region 53; this can be traced back to a slightly different cross-sectional area of the two parts of the channel 28. A lateral offset may also occur as a result of the slightly deviating positioning of the two parts of the channel 28 when producing the continuous opening. It is understood that both the bulges 55 and the lateral offset 56 have been represented in exaggerated fashion for reasons of clarity.

As a result of the material-removing processing with the pulsed laser radiation 35, a hollow structure in the form of a curved channel 28 can be produced in the substrate 25, the said hollow structure having a diameter D of between 1 mm and 20 mm, in particular between 1 mm and 5 mm, and/or a length L_{C} of at least 10 cm, at least 15 cm, at least 20 cm or at least 70 cm. The channel 28 illustrated in FIG. 7B has a length L_{C} of more than 20 cm and a diameter D of 5 mm. The zero-crossing temperature T_{ZC} of the substrate 25 is within the value range specified above and is practically constant in the volume of the monolithic substrate 25, that is to say the variation of the zero-crossing temperature ΔT_{ZC}, that is to say the difference between the maximum zero-crossing temperature and the minimum zero-crossing temperature in the volume of the substrate 25, is likewise in the value range specified above.

A hollow structure 28 which can be used for the passage of a cooling liquid, as described in conjunction with FIGS. 2A and 2B, is generated in the manner described above. Unlike what is described above, the back-side removal can start not from the back side 29 of the substrate 25 but also from a side of the substrate 25 that is opposite to the beam entrance side 27 and arranged within the substrate 25. By way of example, this could be the upper end of the vertical holes illustrated in FIG. 2B, starting from which the two vertical sections 28a,c of the hollow structure 28 are produced. In this case, the hollow structure 28 is produced using a hybrid production method, in which mechanical processing of the substrate 25 is combined with the material-removing processing with pulsed laser radiation 35. It is understood that differently aligned holes or cavities, rather than vertical holes, may serve as a starting point for the above-described production of a hollow structure 28 with the aid of pulsed laser radiation 35.

In summary, high aspect vertical and horizontal, macroscopic hollow structures can be introduced into a substrate 25 of an EUV mirror in the manner described above. It is understood that hollow structures or sections of hollow structures which deviate from a horizontal or vertical alignment can also be produced in this manner. It is understood that it is not only one of the mirrors M1-M6 of the projection system 10, but also any other mirror, in particular EUV mirror, that can be processed in the manner described above in order to generate hollow structures. More complex hollow structures than a single continuous cooling channel 28 can also be produced with the above-described method, for example hollow structures that have Y-branching points or T-branching points. Hollow structures that have branching points can also be produced in the manner described above, without this resulting in damage to, or the occurrence of stress in, the material of the substrate.

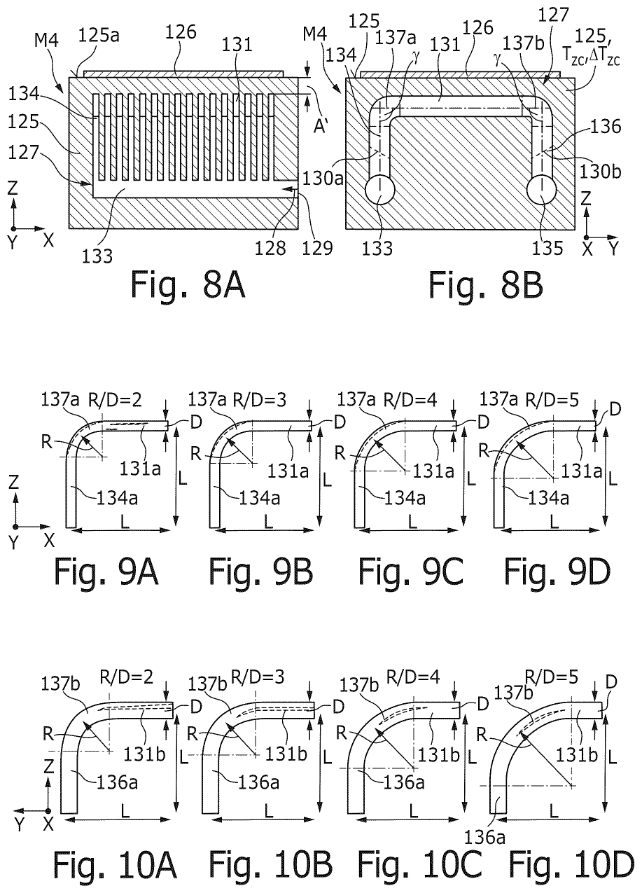

FIGS. 8A and 8B show a further example of an embodiment of the mirror M4 with a monolithic substrate 125, which is part of the projection system 10. In the example shown, the material of the substrate 125 is titanium-doped fused silica with a very small coefficient of thermal expansion. The substrate 125 may also be formed from a different material with a coefficient of thermal expansion that is as small as possible, for example a glass ceramic. The zero-crossing temperature T_{ZC} of the substrate 125 is within the value range specified above and is practically constant in the volume of the monolithic substrate 125, that is to say the variation of the zero-crossing temperature ΔT_{ZC}, that is to say the difference between the maximum zero-crossing temperature and the minimum zero-crossing temperature in the volume of the substrate 125, is likewise in the value range specified above.

A reflective coating 126 is applied to a surface 125a of the substrate 125 for reflection of the EUV radiation 16. A portion of the surface 125a which is located within the reflective coating 126 is struck by the EUV radiation 116 of the projection system 10 and forms an optically used portion of the reflective coating 126 not depicted here. To reflect the EUV radiation 16, the reflective coating 126 may have, for example, a plurality of layer pairs made of materials with different real parts of the refractive index, the layers possibly being formed from Si and Mo, for example, in the case of a wavelength of the EUV radiation 16 of 13.5 nm.

The substrate 125 has a hollow structure 127 through which a fluid 128 can flow, the latter being water in the example shown. The fluid 128 indicated by an arrow in FIG. 8A enters into the substrate 125 via an entrance opening 129 on a side surface in order to flow through a plurality of cooling channels 131, which form a part of the hollow structure 127, in order thus to cool, in particular, the surface 125a of the substrate 125 to which the reflective coating 126 is applied.

To feed the fluid 128 to the inlet opening 129 and to remove the fluid 128 from an outlet opening not depicted in FIGS. 8A and 8B, the projection exposure apparatus 1 comprises the above-described temperature control device 32, which is in the form of a cooling device. In the example shown, the cooling device 32 serves to feed the fluid 128 in the form of cooling water to the hollow structure 127 or to the mirror M4, and to this end comprises a feed line, not depicted here, which is connected to the inlet opening 129 in fluid-tight fashion. The cooling device 132 also comprises a removal line, not depicted here, in order to remove the cooling water via the outlet opening of the substrate 125 or from the hollow structure 127.

As is apparent from FIG. 8A, the fluid 128 enters an inlet channel 133 of the hollow structure 127 via the inlet opening 129, the said inlet channel forming a fluid distributor from which a plurality of distributor channels 134 which are each connected to one of the plurality of temperature control channels referred to as cooling channels 131 below branch off. The cooling channels 131 are arranged with a distance A′ of approx. 5 mm from the surface 125a of the substrate 125, which is planar in the example shown, and extend parallel to the surface 125a, that is to say parallel to an XY-plane of an XYZ-coordinate system. The cooling channels 131 extend in a straight line, are aligned in parallel and run in the longitudinal direction, which corresponds to the Y-direction, over almost the entire portion of the surface 125a of the substrate 125 that is covered by the coating 126; cf. FIG. 8B. From the cooling channels 131, the fluid 128 flows via a plurality of collector channels 136 to a fluid collector, which is formed as an outlet channel 135 in the example shown in FIG. 8B. The outlet channel 135 has the above-described outlet opening, not depicted in FIGS. 8A and 8B, via which the fluid 128 emerges from the hollow structure 127 of the substrate 125.

As is apparent from FIG. 8B, the hollow structure 127 has a first rounded-off section 137a, at which a respective distributor channel 134 merges into a cooling channel 131. Accordingly, the hollow structure 127 also has a second rounded-off section 137b, at which a respective cooling channel 131 merges into a collector channel 136. In the example shown, the cooling channels 131 extend in a straight line in the horizontal direction, which corresponds to the Y-direction, and the distributor channels 134 and the collector channels 136 extend in a straight line in the vertical direction, which corresponds to the Z-direction. Accordingly, the longitudinal axes of the cooling channels 131 are aligned at an angle γ of 90° with respect to the distributor channels 134 and the collector channels 136. The rounded-off section 137a,b serves to generate a flow guidance that is as streamlined as possible in order thus to avoid or at least significantly reduce the occurrence of turbulence, as would occur in the case of a non-rounded-off, “corner-like” 90° bend. The reduction of turbulence has as a consequence a reduction in the flow-induced vibrations of the reflective optical element M4.

For an optimized flow guidance at the 90° bend, it is advantageous if the rounded-off section 137a,b has a constant radius of curvature R, as illustrated in FIGS. 9A-9D and in FIGS. 10A-10D. A salient parameter for an optimal flow guidance is represented by the ratio between the radius of curvature R of the rounded-off section 137a, 137b and the flow diameter D.

FIGS. 9A-9D show the first rounded-off section 137a, at which an end section 131a of a respective cooling channel 131 and a distributor channel section 134a adjacent to the end section 131a are adjacent to one another, in the case of four different ratios between the radius of curvature R of the rounded-off section 137a and the diameter D of the rounded-off section 137A. In this case, the radius of curvature R is measured in the centre of the rounded-off section 137a, as illustrated in FIGS. 9A-9D. The diameter D of the rounded-off section 137a is 5 mm in all four examples shown. The diameter D of the rounded-off section 137a in this case corresponds to the diameter D of the distributor channel 134 and the diameter D of the cooling channel 131. The length L is approx. 50 mm in the illustrations of FIGS. 9A-9D. As is apparent from FIGS. 9A-9D, the R/D ratio is R/D=2, R/D=3, R/D=4 and R/D=5, respectively, in the four examples shown.

In a manner analogous to FIGS. 9A-9D, FIGS. 10A-10B show the second rounded-off section 137b, at which an end section 131b of a respective cooling channel 131 and a collector channel section 136a adjacent to the end section 131b merge into one another. The diameter D of the rounded-off section 137b is 10 mm in FIGS. 10A-10D. In the illustrations of FIGS. 10A-10D, the length L is approx. 60 mm. In the illustration of FIGS. 10A-10D, the R/D ratio is also R/D=2, R/D=3, R/D=4 and R/D=5, respectively, in the four examples shown. The diameter D of a respective rounded-off section 137a, 137b is typically between 2 mm and 20 mm, ideally between 2 mm and 12 mm.

As described above, there is an optimal ratio between the radius of curvature R and the diameter D of the respective rounded-off section 137a, 137b, at which the centrifugal force acts such that the pressure of the flowing fluid 128 at the outer side of the rounded-off section 137a, 137b is increased only minimally in comparison with the inner side of the rounded-off section 137a,b and this allows a reduction in the boundary layer separation to be attained upstream and downstream of the rounded-off section 137a,b. FIGS. 9A-9D and FIGS. 10A-10D illustrate the contours of regions in which the turbulent kinetic energy of the flowing fluid 128 exceeds a specified value. In this case, the assumption was made that the fluid 128 flows from the distributor channel section 134a or from the collector channel section 136a into the respective end section 131a or 131b of the cooling channel 131.

To this end, a ratio between the radius of curvature R of the rounded-off section 137a, 137b and the diameter D of the rounded-off section 137a, 137b of between 2 and 6, better between 2.5 and 5, ideally between 2.5 and 3.5, was found to be particularly advantageous. There can typically be no significant reduction in the boundary layer separation in the case of an R/D ratio of less than 2. An optimal value for the R/D ratio is typically between 2.5 and 3.5, but the optimal value may optionally also be outside of this value range. There is typically a deterioration in the flow behaviour in the case of an R/D ratio of more than 6.0.

In practice, the rounded-off section 137a,b cannot be produced with the aid of conventional processing methods in a monolithic substrate 125, as described above. In the example shown, only the inlet channel 133 and the outlet channel 135 are produced by a conventional processing method, to be precise by virtue of a respective hole being introduced into the substrate 125. By contrast, the distributor channels 134, the cooling channels 131 and the collector channels 136 are produced by laser ablation of the material of the substrate 25, the laser ablation being described below.

To produce the distributor channels 134, the cooling channels 131 and the collector channels 136 of the hollow structure 127, a pulsed laser beam is radiated to the upper side of the inlet channel 133 through the material of the substrate 125 starting from the surface 125a of the substrate 125, and is focused there, before the reflective coating 126 is applied, with a movement pattern having a plurality of parallel ablation paths being generated, the said ablation paths forming a removal front 130a, which is aligned at an angle of 45° with respect to the thickness direction Z of the substrate 25. Starting from this position, the removal front 130a is displaced multiple times relative to the substrate 125 in the thickness direction, which corresponds to the Z-direction, in order to ablate the material of the substrate 125 and in order to form the distributor channel 34. During the displacement, the removal front 130a may remain stationary and the substrate 125 is displaced upwards in the Z-direction until the removal front 130a is situated just below the first rounded-off section 137a.

To produce the first rounded-off section 137a, the removal front 130a or the substrate 125 is displaced in a superposed movement both in the Z-direction and in the Y-direction. After the first rounded-off section 137a is formed, the removal front 130a aligned at 45° with respect to the thickness direction corresponding to the Z-direction is now only displaced in the longitudinal direction of the cooling channel 131 corresponding to the Y-direction, for forming the said cooling channel 131 or the end section 131a of the said cooling channel 131 adjacent to the distributor channel 134, until the said removal front is situated approximately in the centre of the cooling channel 131 in the longitudinal direction.

The production of the collector channel 136, the second rounded-off section 137b and the second half of the cooling channel 131 or the end section 131b adjacent to the second rounded-off section 137b is implemented analogously through laser ablation starting from the outlet channel 135, on the upper side of which the pulsed laser radiation is initially focused through the substrate 125. The further removal front 30b formed in the process is likewise aligned at 45° with respect to the thickness direction of the substrate 25 or the XY-plane but is mirrored in relation to the XZ-plane vis-à-vis the above-described removal front 130a. The alignment of the removal front 130a, 130b at an angle to the thickness direction or the incoming radiation direction Z of the pulsed laser beam or the pulsed laser radiation is typically implemented in the manner described above in the context of FIGS. 4A-4C and FIGS. 5A and 5B. A fluid is fed to the respective removal front 130a, 130b for removing ablated material from the respective removal front 130a, 130b or for cooling purposes. The feed of the fluid is implemented with a fluid feed, typically in the manner described in the context of FIGS. 6A-6C, that is to say through an at least partial introduction of a fluid feed into the hollow structure 127.

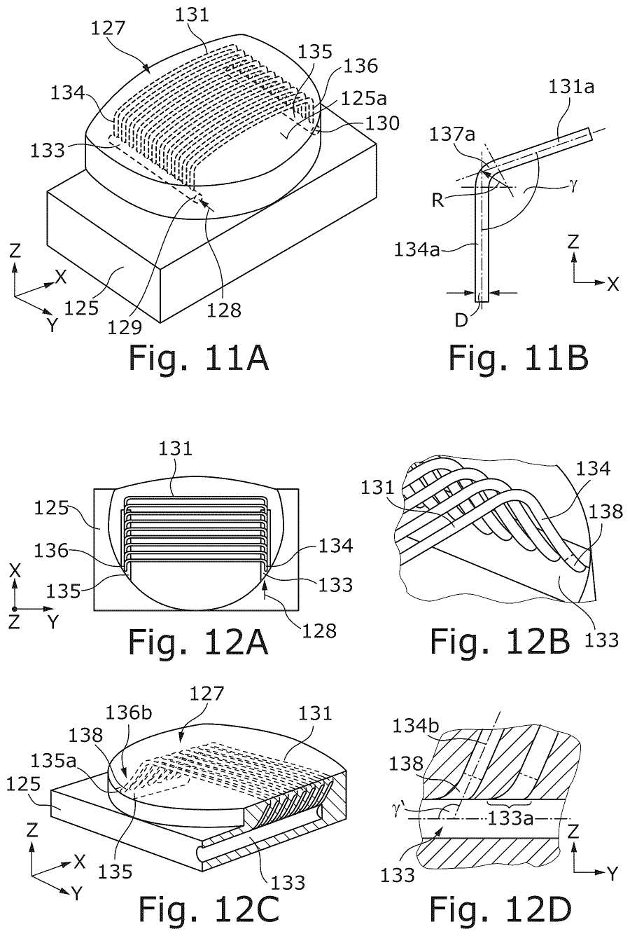

In the above-described hollow structure 127, it is only the two sections 137a, 137b that are rounded-off, while the distributor channels 134, the collector channels 136 and the cooling channels 131 extend in a straight line. However, more complex hollow structures 127 can also be produced with the aid of the above-described laser ablation method. FIGS. 11A and 11B show an example of such a hollow structure 127 in a substrate 125, which substantially corresponds to the hollow structure 127 illustrated in FIGS. 8A and 8B. The hollow structure 127 differs from the hollow structure 127 in FIGS. 8A and 8B in that the cooling channels 131 have a minor curvature, which follows the curvature of the surface 125a which is convexly curved in the example shown. In the example shown in FIG. 11B, an end section 131a of the respective cooling channel 131 neighboring the distributor channel 134 is aligned at an angle γ of approx. 115°. Despite the fact that the cooling channel 131 has a curvature extending in the ZX-plane, it is possible to define a longitudinal axis, which defines the angle γ, for the end section 131a adjacent to the rounded-off section 131a. It is understood that the second rounded-off section 137b, which is not depicted in FIGS. 11A and 11B, is embodied in a manner corresponding to the first section 137a. The R/D ratio between the radius of curvature R and the diameter D of the respective rounded-off sections 137a,b is typically in the value range described above.

In the case of the substrate 125 shown in FIGS. 12A-12D, the hollow structure 127 is designed substantially like the hollow structure 127 shown in FIGS. 8A and 8B, but differs from the latter in that the distributor channels 134 and the collector channels 136 do not extend in the vertical direction but are aligned at an angle of approx. 25° with respect to the thickness direction Z of the substrate 125. Like the hollow structure 127 shown in FIGS. 8A and 8B, the hollow structure 127 shown in FIGS. 12A-12D has two rounded-off sections 137a, 137b, not depicted here, between the respective distributor channels 134 or collector channels 136 and the cooling channels 131. The angle γ between the distributor channels 134 or the collector channels 136 and the cooling channels 131 is also 90° in this case, but it runs in a plane that is inclined by approx. 25° with respect to the thickness direction Z, as is apparent from FIG. 12D, which shows an angle γ′ of approximately 115° between the longitudinal axis of the inlet channel 133 and a respective distributor channel 134.

The hollow structure 127 shown in FIGS. 12A-12D has rounded-off sections 138, at which a merging section 134b of a respective distributor channel 134 transitions into the inlet channel 134, more precisely into a branching section 134a of the inlet channel 134, or at which a merging section 136b of a respective collector channel 136 transitions into a branching section 135a of the outlet channel 135. In the example shown, the respective rounded-off section 138 does not have a constant diameter or flow cross section; instead, the flow cross section reduces starting from the branching section 134a. The rounded-off section 138 also does not have a constant radius of curvature R, as is the case for the two curved sections 137a,b which extend between the respective distributor channels 134 or collector channels 136 and a respective cooling channel 131. Accordingly, it is not possible to specify an optimized ratio of radius of curvature R to diameter D. The rounded-off section 138 can also be produced with the aid of the above-described laser ablation method.

It is understood that the hollow structure 127, which has the at least one rounded-off section 137a,b, 138, is not restricted to the above-described examples but that, in principle, other, more complex hollow structures 127, which have one or more such sections, may also extend through the substrate 125. Additionally, it is not only the cooling channels 131 which have a curvature as described in the context of FIGS. 11A and 11B, but, rather, the distributor channels 134 and the collector channels 136 may also extend in curved fashion.

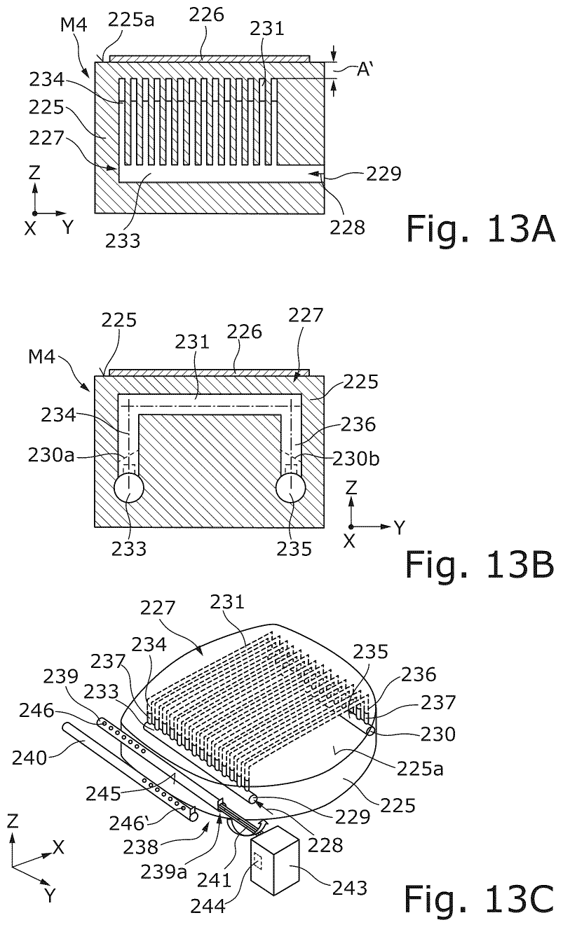

FIGS. 13A and 13B show a further example of a mirror M4 with a monolithic substrate 225 in the example shown, which is part of the projection system 10. In the example shown, the material of the substrate 225 is titanium-doped fused silica with a very small coefficient of thermal expansion. The substrate 225 may also be formed from a different material with a coefficient of thermal expansion that is as small as possible, for example a glass ceramic.

A reflective coating 226 is applied to a surface 225a of the monolithic substrate 225. A portion of the surface 225a which is located within the reflective coating 226 is struck by the EUV radiation 16 of the projection system 10 and forms an optically used portion of the reflective coating 226 not depicted here. To reflect the EUV radiation 16, the reflective coating 226 may have, for example, a plurality of layer pairs made of materials with different real parts of the refractive index, the layers possibly being formed from Si and Mo, for example, in the case of a wavelength of the EUV radiation 16 of 13.5 nm.

The substrate 225 has a hollow structure 227 through which a fluid 228 can flow, the latter being water in the example shown. The fluid 228 indicated by an arrow in FIG. 13A enters into the substrate 225 via an entrance opening 229 on a side surface in order to flow through a plurality of cooling channels 231, which form a part of the hollow structure 227, in order thus to cool, in particular, the surface 225a of the substrate 225 to which the reflective coating 226 is applied.

To feed the fluid 228 to the inlet opening 229 and to remove the fluid 228 from an outlet opening of the substrate 225 not illustrated in FIG. 13C, the projection exposure apparatus 1 comprises a temperature control device in the form of a cooling device 32, which is depicted very schematically in FIG. 1. In the example shown, the cooling device 32 serves to feed the fluid 228 in the form of cooling water to the hollow structure 227 or to the mirror M4, and to this end comprises a feed line, not depicted here, which is connected to the inlet opening 229 in fluid-tight fashion. The cooling device 32 also comprises a removal line, not depicted here, in order to remove the cooling water via the outlet opening of the substrate 225 or from the hollow structure 227. The other mirrors M1-M3, M5, M6 of the projection system 10 and the mirrors of the illumination system 2 may also, for cooling purposes, be connected to the cooling device 32 or optionally to further temperature control or cooling devices provided to this end.

As is apparent from FIG. 13A, the fluid 228 enters a first cavity 233 of the hollow structure 227 via the inlet opening 229, the said cavity forming a fluid distributor from which a plurality of distributor channels 234 which are each connected to one of the plurality of cooling channels 231 branch off. The cooling channels 231 are arranged with a distance A′ of approx. 2 mm to approx. 5 mm from the surface 225a of the substrate 225, which is planar in the example shown, and extend parallel to the surface 225a, that is to say parallel to an XY-plane of an XYZ-coordinate system. The cooling channels 231 extend in a straight line, are aligned in parallel and run in the longitudinal direction, that is to say in the Y-direction, over almost the entire portion of the surface 225a of the substrate 225 that is covered by the coating 226; cf. FIG. 13B. From the cooling channels 231, the fluid 228 flows via a plurality of collector channels 236 to a fluid collector, which is formed as a second cylindrical cavity 235 in the example shown in FIG. 13B. The fluid 228 emerges from the hollow structure 227 of the substrate 225 via the outlet opening 230. In the example shown, the cooling channels 231 extend in a straight line in the horizontal direction, which corresponds to the X-direction, and the distributor channels 234 and the collector channels 236 extend in a straight line in the vertical direction, which corresponds to the Z-direction. Accordingly, the longitudinal axes of the cooling channels 231 are aligned at an angle of 90° with respect to the distributor channels 234 and the collector channels 236. However, such an alignment is not mandatory.

The following procedure is carried out to produce the hollow structure 227 shown in FIGS. 13A-13C: Initially, the two circular cylindrical cavities 233, 235, which form the fluid distributor and the fluid connector, are introduced into the material of the substrate 225 by mechanical processing, for example by grinding or ultrasonic grinding. Subsequently, the substrate 225 is immersed in a liquid bath, more precisely a water bath, as a result of which a fluid 228 in the form of water enters the cavity 233 of the fluid distributor through the inlet opening 228 and enters the cavity 235 of the fluid collector through the outlet opening 230 and fills these cavities. Starting from the respective cavities 233, 235 filled with the fluid 238, a plurality of short channel sections 237 adjacent to the cavities 233, 235 are produced by multi-photon laser ablation, as is apparent from FIG. 13C.

To produce the channel sections 237, a plurality of pulsed laser beams are radiated through the material of the substrate 225 at the surface of the cavity 233, which forms the fluid distributor, starting from the surface 225a of the substrate 225 and are focused there. Therefore, the top side of the cavity 233 forms a side of the substrate 225 that is opposite to the radiation entrance side in the form of the surface 225a. Through a respective radiated-in pulsed laser beam, the focal region is moved in a movement pattern with a plurality of parallel ablation paths that are offset from one another in the Z-direction and form a removal front 230a which is aligned at an angle of approx. 45° with respect to the thickness direction Z of the substrate 225. The focal position of the radiated-in laser beam is modified in the Z-direction to bring about the offset of the ablation paths in the Z-direction.

Starting from the point on the surface of the cavity 233 from which the channel section 237 starts, the removal front 230a is displaced multiple times in the thickness direction, that is to say in the Z-direction, relative to the substrate 225 in order to ablate the material of the substrate 225 and in order to form the channel section 237. During the displacement, the removal front 230a may remain stationary and the substrate 225 is displaced downwards in the Z-direction until the removal front 230a has a distance of approx. 20-40 mm from the upper side of the cavity 233. To produce a channel section 237 with a relatively long length through multi-photon laser ablation, it is necessary for the removal front 230a to be locally rinsed with a fluid 228, as described in more detail below. The production of channel sections 237 that start from the cavity 235 which forms the fluid collector is implemented in a corresponding manner through multi-photon laser ablation. A further removal front 230b formed in the process is likewise aligned at approx. 45° with respect to the thickness direction of the substrate 225 or the XY-plane but is mirrored in relation to the XZ-plane vis-à-vis the above-described removal front 230a.

To form the hollow structure 227 shown in FIGS. 13A-13B, the substrate 225 is taken from the liquid bath and the liquid 228 is removed from the cavities 233, 235. To produce the remaining hollow structure 227, use is made of a fluid feed apparatus 238 to feed a fluid 228 in the form of water to the respective removal front 230a, 230b, which is depicted very schematically in FIG. 13C. The fluid feed apparatus 238 comprises two insertion components 239, 240 and a plurality of flexible fluid lines 241. In the example shown, the fluid feed apparatus 238 comprises seven fluid lines 241. The fluid lines 241 are connected to a fluid provision device 243 of the fluid feed apparatus 238, which has a pump to pump the fluid 228 in the flexible fluid lines 241 at a pressure which is generally at several bars. The fluid provision device 243 also comprises a tracking device 244 which serves the tracking by, more precisely the pushing of, the flexible fluid lines 241 when the removal fronts 230a, 230b are moved in the substrate 225 in order to form the hollow structure 227. By way of example, the tracking device 244 may comprise a reel or the like, on which a section of the respective flexible fluid line 241 is wound up. For tracking purposes, the reel can be rotated at a constant angular speed which corresponds to the speed of movement of the removal front. It is understood that the tracking device 244 may also be formed differently.

To produce the hollow structure 277, the first rod-shaped, cylindrical insertion component 239 is introduced through the inlet opening 229 into the first cavity 233 until the said insertion component rests with its end face against the end of the first cavity 233, which forms a blind hole. In the circumferential direction, the insertion component 239 is aligned so that openings 246 that are formed in a lateral surface 245 of the insertion component 239 are positioned at those positions on the wall of the cavity 233 from which a number of channel sections 237, which correspond to the number of openings 246, start or branch from the cavity 233. The alignment of the insertion component 239 in the circumferential direction can also be implemented by virtue of a laterally protruding section being provided at the end face 239a of the rod-shaped insertion component 239, cf. FIG. 13C, which projection serves as a tongue and engages in a correspondingly shaped groove on the side surface of the substrate 225, as illustrated using dashed lines in FIG. 13B.

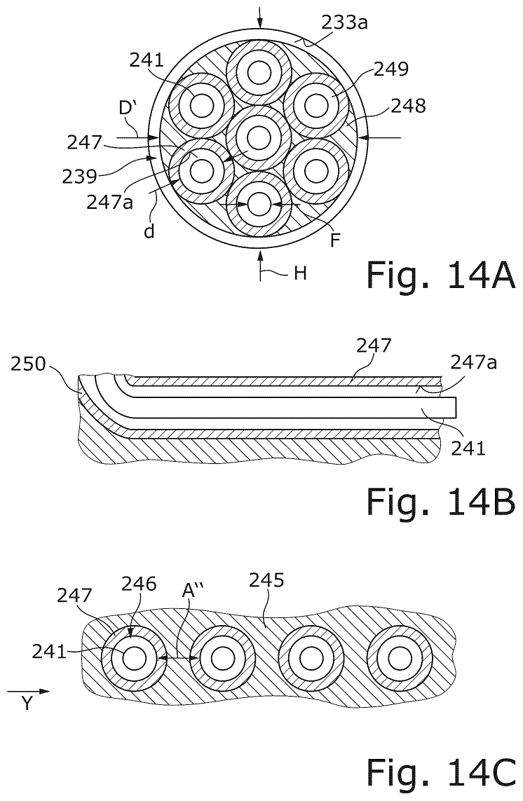

To introduce the flexible fluid lines 241 into the channel sections 237, the insertion component 239 comprises seven guide channels 247 in the example shown; cf. FIG. 14A-14C.

It is understood that the insertion component 239 may also have a greater or a fewer number of guide channels 247. As is evident from FIG. 14A, which shows the insertion component 239 in a plan view of its end face 239a illustrated in FIG. 13C, six of the guide channels 247 are arranged around a central guide channel 247. In the example shown in FIGS. 14A-14C, the guide channels 247 are stainless steel pipes which are embedded or cast in a solid material 248, which defines the diameter D′ of the insertion component 39, approx. 9 mm in the example shown. The diameter H of the cylindrical cavity 233, more precisely of its inner wall 233a, is slightly larger and is approx. 10 mm. The internal diameter d of a respective guide channel 247 is approx. 2 mm. The internal diameter F of a respective flexible fluid line 241 is approx. 1 mm.

As is quite apparent from FIG. 14A, a respective fluid line 241 extends in the centre of a respective guide channel 247. A ring gap 249 is situated between the fluid line 241 and an inner wall 247a of a respective guide channel 247. The ring gap 249 serves to return the fluid 228 which is fed to a respective removal front 230a, 230b through the flexible fluid line 241. The returned fluid 228 emanates from the end face 239a of the insertion component 239 and is removed from there.

As is apparent from FIG. 14B, a respective guide channel 247 of the insertion component 239 has a rounded-off section 250 for changing the alignment of the flexible fluid line 241 from a direction parallel to the longitudinal direction, which corresponds to the Y-direction, of the insertion component 239 to a direction perpendicular thereto so that the flexible fluid line 241 can emerge at a respective opening 246 in the lateral surface 245 of the rod-shaped insertion component 239. The rounded-off section 250 is produced by bending a respective stainless steel pipe which forms the guide channel 247.

As is apparent from FIG. 13C and FIG. 14C, the openings 246 in the lateral surface 245 of the insertion component 239 are arranged along a common line which corresponds to the longitudinal direction, that is to say the Y-direction, of the insertion component 239. This is typically necessary because the channel sections 237 likewise extend along a common line which corresponds to the longitudinal direction, that is to say the Y-direction, of the cavity 233. The distance A″ between neighboring openings 246 in the lateral surface 245 corresponds to the distance between two adjacent channel sections 237 in the substrate 225. It is not mandatory for the channel sections 237 and the openings 246 in the lateral surface of the insertion component 239 to run along a common line; rather, deviations from such an arrangement along a common line are possible.

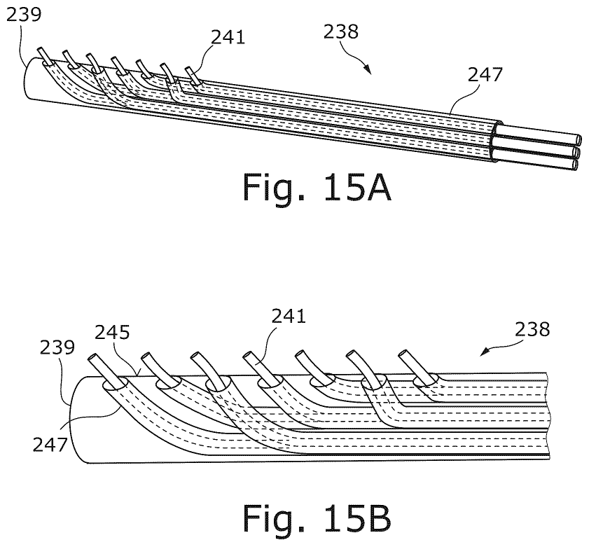

To arrange the openings 246 in the lateral surface 245 next to one another in the longitudinal direction, it is typically necessary to design the guide channels 247 with different lengths and twist the curved sections 250 with respect to one another, as is quite apparent from FIGS. 15A and 15B, which show an insertion component 239 that differs from the insertion component 239 shown in FIGS. 14A-14C in that it was produced by an additive manufacturing method. The insertion component 239 shown in FIGS. 15A and 15B consists of a cylindrical main body, in which the guide channels 247 were formed during additive manufacturing.

The free ends of the fluid lines 241 which protrude beyond the lateral surface 245 of the insertion component 239 and which are illustrated in FIG. 15B protrude into the channel sections 237 during the operation of the fluid feed apparatus 238. To produce the part of the hollow structure 227 illustrated using dashed lines in FIG. 13C, a removal front 230a, 230b is produced at the end faces of the already formed channel sections 237 by radiating in pulsed laser radiation. The end faces of the already formed channel sections 237 form a side of the substrate 225 that is opposite to the radiation entrance side and starting from which the removal front 230a, 230b is moved relative to the substrate 225 by virtue of the substrate 225 being displaced downwards in the Z-direction until the removal front 230a is level with the horizontally extending cooling channel 231. Alternatively, for example, the focal position of the radiated-in pulsed laser radiation can be offset upwards by the same value at all points along the removal front 230a in order to move the removal front 230a in the substrate 225 while the substrate 225 itself remains stationary.

To form the horizontal cooling channel 231, the removal front 230a that is aligned at approx. 45° with respect to the thickness direction, that is to say the Z-direction, of the substrate 225 or with respect to the incoming radiation direction of the pulsed laser radiation is displaced in the longitudinal direction, that is to say in the X-direction, of the cooling channel 231 until it is situated approximately in the centre of the cooling channel 231. In this case, the substrate 225 is typically at rest and the optical unit for radiating the laser beams onto the substrate 225 is displaced and moved in a suitable fashion in order to displace the removal front 230a in the horizontal direction.

Using a further insertion component of a further fluid feed device not depicted here, a plurality of seven collector channels 235 are typically produced concurrently starting from the second cavity 235 by multi-photon laser ablation by virtue of the substrate 225 being displaced downwards or by virtue of the focal position of the radiated-in pulsed laser radiation being displaced upwards by a constant value at each point of the removal front 230b, with the substrate 225 remaining stationary. The removal front 230b is subsequently moved in the Y-direction with the substrate 225 at rest. There is an overlap of the two removal fronts 230a, 230b approximately in the middle of a respective cooling channel 231, which may for example have a length of approx. 400 mm, as a result of which a continuous cooling channel 231 is formed, and is connected through the distributor channel 234 to the first cavity 233 that serves as a fluid distributor and through the collector channel 236 to the second cavity 235 that serves as a fluid collector.

In the manner described above, it is possible to simultaneously produce seven distributor channels 234, cooling channels 231 and collector channels 236, as a result of which the time required to produce the hollow structure 227 can be significantly reduced. To produce the remaining seven distributor channels 234, cooling channels 231 and collector channels 236 of the hollow structure 227 illustrated in FIG. 13C, use can be made of the insertion component 240 illustrated in FIG. 13C, in the case of which the openings 246′ for the emergence of the fluid lines 241 are offset in relation to the openings 246 of the first insertion component 239. The production of the second group of seven distributor channels 234, cooling channels 231 and collector channels 236 is implemented analogously to the production of the first group, by virtue of the second insertion component 240 being inserted into the first cavity 233.

It is understood that, unlike what is illustrated in FIG. 13C, the second insertion component 240 may have a shorter length than the first insertion component 239. Should this be the case, a spacer, for example in the form of a solid cylinder, may be introduced into the cavity 233 before the insertion of the second insertion component 240, the insertion component 240 being brought to rest against the end face of the said spacer when it is pushed in. Alternatively, one or more protruding sections at the end face of the insertion component 240 may serve as a stopper or as a rest surface for restricting the movement of the second insertion component 240 during the introduction into the cavity 233. The stoppers attached to the end face of the second insertion component 240 may also serve as tongues and engage in corresponding grooves in the outer side of the substrate 225 in order, as described above, to suitably align the second insertion component 240 in the circumferential direction.

Within the scope of the production of complex hollow structures 227 as depicted in FIG. 13C, a plurality of simultaneously produced removal fronts 230a, 230b can be tracked in automated fashion by the flexible fluid lines 241 with the aid of the above-described fluid feed apparatus 238. Thereby, a plurality of structures, for example cooling channels 231, can be produced concurrently, having as a consequence significant savings in time or an increase in productivity when producing the complex hollow structure 227.

The fluid feed 50 described above in the context of FIGS. 6A-6C may for example be designed as the fluid feed apparatus 238 described in the context of FIG. 13C, FIGS. 14A-14C and FIGS. 15A and 15B. However, it is also possible that the fluid feed 50 only comprises some of the constituent parts of the fluid feed apparatus 238, for example the fluid provision device 243 and optionally the tracking device 244. The latter can be used, for example, for automated tracking by at least one flexible fluid line 241 in the form of the flexible tubing 52 described in the context of FIGS. 6A-6C.

The present invention also includes aspects defined in the following clauses, which form part of the description but are not claims.

1. Method for producing a hollow structure (28) in a workpiece (25), in particular in a substrate for an EUV mirror (M4), through material-removing processing with pulsed laser radiation (35), comprising:
radiating the pulsed laser radiation (35) into the workpiece (25) which is formed from a material transparent to the pulsed laser radiation (35) from a radiation entrance side (27),
focusing the pulsed laser radiation (35) into a focal region (39),
forming a removal front (46) for the areal removal of material of the workpiece (25) by moving the focal region (39) along mutually offset trajectories (42) of a movement pattern (41), and producing the hollow structure (28) by moving the removal front (46) within the workpiece (25) starting from a side (29) of the workpiece (25) that is opposite to the radiation entrance side (27), characterized
in that a removal front (46) that is not aligned perpendicular to an incoming radiation direction (Z) of the pulsed laser radiation (35) at the radiation entrance side (27) of the workpiece (25) is formed at least intermittently during the production of the hollow structure (28).

2. Method according to clause 1, wherein a removal front (46) aligned at an angle (a) of between 20° and 70°, preferably between 30° and 60° with respect to the incoming radiation direction (Z) of the pulsed laser radiation (35) at the radiation entrance side (27) of the workpiece (25) is formed at least intermittently.

3. Method according to clause 1 or 2, wherein, for forming the removal front (46) that is not aligned perpendicular to the incoming radiation direction (Z), the trajectories (42) of the movement pattern (41) are offset from one another in the incoming radiation direction (Z) by virtue of the focal region (39) being offset in the incoming radiation direction (Z).

4. Method according any one of the preceding clauses, wherein a pulse energy (E_{P}) of the pulsed laser radiation (35) of the mutually offset trajectories (42) of the movement pattern (41) is modified to form the removal front (46) that is not aligned perpendicular to the incoming radiation direction (Z), with the focal region (39) preferably being moved in a plane (FE) perpendicular to the incoming radiation direction (Z).

5. Method according to any one of the preceding clauses, wherein the removal front (46) is moved at least intermittently in a movement direction (−X) transverse to the incoming radiation direction (Z) within the workpiece during the production of the hollow structure (28) in order to form a section (28b) of the hollow structure (28) which preferably extends substantially parallel to the radiation entrance side (27), with the removal front (46) at its edge (46a) closer to the radiation entrance side (27) preferably being aligned at an angle (β) of less than 90°, preferably less than 70° with respect to the movement direction (−X), when moving transversely to the incoming radiation direction (Z).

6. Method according to any one of the preceding clauses, wherein the removal front (46) is moved at least intermittently in a manner substantially parallel to the incoming radiation direction (Z) during the production of the hollow structure (28) in order to produce a section (28a) of the hollow structure (28) which extends substantially parallel to the incoming radiation direction (Z), starting from the side (29) of the workpiece (25) that is opposite to the radiation entrance side (27), and preferably in order to produce a further section (28c) of the hollow structure (28) which extends substantially parallel to the incoming radiation direction (Z).

7. Method according to any one of the preceding clauses, wherein a first section (28a, 28c) of the hollow structure (28) and a second, adjacent section (28b) of the hollow structure (28) are produced, the longitudinal directions (X, Z) of which are aligned with respect to one another at an angle (γ) of between 70° and 100°, preferably at an angle (γ) of 90°.

8. Method according to clause 7, wherein a rounded-off section (28d, 28e) is formed during the production of the hollow structure (28), the first section (28a, 28c) and the second section (28b) merging into one another in the said rounded-off section.

9. Method according to any one of the preceding clauses, wherein the removal front (46) is brought into contact with a fluid (32b) when the hollow structure (28) is produced, the fluid (32b) tracking the removal front (46), preferably with a flexible tubing (52), when the removal front (46) is moved starting from the side (29) of the workpiece (25) distant from the radiation entrance side (27).

10. Method according to any one of the preceding clauses, wherein the workpiece is displaced for moving the removal front (46).

11. Method according to any one of the preceding clauses, wherein the focal region (39) is moved along the mutually offset trajectories (42) of the movement pattern (41) with a scanner optical unit (36) in order to form the removal front (46).

12. Method according to any one of the preceding clauses, wherein the substrate (25) is monolithic and consists of titanium-doped fused silica or a glass ceramic.

13. EUV mirror (M4), comprising:
a substrate (25),
a coating (26) applied to the substrate (25) and serving to reflect EUV radiation (16), characterized
in that the substrate (25) comprises at least one hollow structure (28) produced using the method according to any one of the preceding clauses.

14. EUV lithography system (1), comprising: at least one EUV mirror (M4) according to clause 13, and a cooling device (32) which is designed to allow a cooling fluid (32a) to flow through the at least one hollow structure (28).

15. Apparatus (33) for producing at least one hollow structure (28) in a workpiece (25), in particular in a substrate for an EUV mirror (M4), comprising:
a laser source (34) for producing pulsed laser radiation (35),
a focusing device (37) for focusing the laser radiation (35) into a focal region (39),
a holder (44) for receiving the workpiece (25),
a scanner optical unit (36) designed to radiate the pulsed laser radiation (35) onto a radiation entrance side (27) of the workpiece (25) received by the holder (44) and to move the focal region (39) along mutually offset trajectories (42) of a movement pattern (41) in order to form a removal front (46) for the areal removal of material of the workpiece (25), and
a positioning device (43) for moving the removal front (46) within the workpiece (25) starting from a side (29) of the workpiece (25) that is opposite to the radiation entrance side (27) in order to produce the hollow structure (28), characterized
in that the apparatus (33) is designed to form a removal front (46) that is not aligned perpendicular to an incoming radiation direction (Z) of the pulsed laser radiation (35) at the workpiece (25) received by the holder (44).

16. Apparatus according to clause 15, further comprising: a focus offset device (47) for offsetting the focal region (39) of the pulsed laser radiation (35) in the incoming radiation direction (Z), and
a control device (48) which is designed to control the focus offset device (47) to offset trajectories (42) of the movement pattern (41) with respect to one another in the incoming radiation direction (Z) in order to form the removal front (46) that is not aligned perpendicular to the incoming radiation direction (Z).

17. Apparatus according to clause 15 or 16, further comprising:
a control device (48) which is designed to control the laser source (34) to modify a pulse energy (E_{P}) of the pulsed laser radiation (35) of the mutually offset trajectories (42) of the movement pattern (41) in order to form the removal front (46) that is not aligned perpendicular to the incoming radiation direction (Z).

18. Apparatus according to any one of clauses 15 to 17, wherein the positioning device (43) is designed to displace the workpiece (25) in the incoming radiation direction (Z) and preferably in at least one direction (X, Y) transverse to the incoming radiation direction (Z).

19. Apparatus according to any one of clauses 15 to 18, further comprising:
a fluid feed (50) designed to feed a fluid (32b) to the removal front (46), the fluid feed (50) preferably having a flexible tubing (52) for tracking by the fluid (32b) when the removal front (46) is moved starting from the side (29) of the workpiece (25) that is opposite to the radiation entrance side (27).

20. Optical element (M4) for reflecting radiation, in particular for reflecting EUV radiation (16), comprising:
a monolithic substrate (25),
a reflective coating (26) that is applied to a surface (25a) of the monolithic substrate (25), and at least one hollow structure (27) which extends in the monolithic substrate (25) and is designed to allow a fluid (28) to flow therethrough, with the hollow structure (27) having a first section (31a, 31b; 34b, 36b) and a second, neighboring section (34a, 36a; 33a, 35a), which are aligned with respect to one another at an angle (γ, γ′) of between 60° and 120°, preferably at an angle (γ, γ′) of between 80° and 100°, in particular at an angle (γ, γ′) of 90°, characterized
in that the hollow structure (27) has a rounded-off section (37a, 37b, 38), at which the first section (31a, 31b; 34b, 36b) and the second section (34a; 36a; 33a, 35a) merge into one another.

21. Optical element according to clause 20, wherein an R/D ratio between a radius of curvature R of the rounded-off section (37a, 37b) and a diameter D of the rounded-off section (37a, 37b) is between 2 and 6, preferably between 2.5 and 5, in particular between 2.5 and 3.5.

22. Optical element according to clause 20 or 21, wherein the diameter D of the rounded-off section (37a, 37b) is between 2 mm and 20 mm, preferably between 2 mm and 12 mm.

23. Optical element according to any one of clauses 20 to 22, wherein the hollow structure (27) comprises a plurality of cooling channels (31) which extend below the surface (25a) to which the reflective coating (26) is applied, and wherein the hollow structure (27) comprises a fluid distributor (33) connected to the cooling channels (31) via distributor channels (34) and a fluid collector (35) connected to the cooling channels (31) via collector channels (36).

24. Optical element according to clause 23, wherein the first section forms an end section (31a) of the cooling channel (31) adjacent to a distributor channel (34) and the second section forms a distributor channel section (34a) adjacent to the end section (31a) and/or wherein the first section forms an end section (31b) of the cooling channel (31) adjacent to a collector channel (36) and wherein the second section forms a collector channel section (36a) adjacent to the end section (31b).

25. Optical element according to clause 23 or 24, wherein the fluid distributor forms an inlet channel (33), from which the distributor channels (34) branch off, and/or wherein the fluid collector forms an outlet channel (35), from which the collector channels (36) branch off.

26. Optical element according to clause 25, wherein the first section forms a merging section (34b) of the distributor channel (34) neighboring the inlet channel (33) and wherein the second section forms a branching section (33a) of the inlet channel (33) neighboring the merging section (34b) and/or wherein the first section forms a merging section (36b) of the collector channel (36) neighboring the outlet channel (35) and wherein the second section forms a branching section (35a) of the outlet channel (35) neighboring the merging section (36b) of the collector channel (36).

27. Optical element according to clause 26, wherein the angle (γ′) between the branching section (33a) of the inlet channel (33) and the merging section (34b) of the distributor channel (34) is greater than 90°, preferably greater than 100°, and/or wherein the angle (γ′) between the branching section of the outlet channel (35) and the merging section (36b) of the collector channel (35) is greater than 90°, preferably greater than 100°.

28. Optical element according to any one of clauses 20 to 27, wherein the material of the substrate (25) is selected from the group comprising: fused silica, in particular titanium-doped fused silica, and glass ceramic.

29. Optical arrangement, in particular an EUV lithography system (1), comprising:
at least one optical element (M4) according to any one of clauses 20 to 28, and a temperature control device, in particular a cooling device (32) which is designed to allow a fluid (28) to flow through the at least one hollow structure (27).

30. Fluid feed apparatus (38) for feeding a fluid (28) to at least one ablation front (30a, 30b) when removing material from a workpiece through multi-photon laser ablation, preferably from an in particular monolithic substrate (25) for an EUV mirror (M4), comprising:
at least one flexible fluid line (41), preferably a plurality of flexible fluid lines (41), for feeding the fluid (28) to the at least one ablation front (30a, 30b) and
at least one insertion component (39, 40) for insertion into a cavity (33, 35) of the workpiece (25), the insertion component (39, 40) having at least one guide channel (47) in which the at least one flexible fluid line (41) is guided in order to feed the fluid (28) to the at least one ablation front (30a, 30b).

31. Fluid feed apparatus according to clause 30, wherein the insertion component (39, 40) has a plurality of guide channels (47) in which a flexible fluid line (41) is guided in each case.

32. Fluid feed apparatus according to clause 30 or 31, wherein a gap through which fluid can flow, in particular a ring gap (49), is formed between the fluid line (41) and a channel wall (47a) of the guide channel (47) in order to return the fluid (28) from the ablation front (30a, 30b).

33. Fluid feed apparatus according to any one of clauses 30 to 32, wherein the guide channel (47) has at least one rounded-off section (50) for changing the direction of the flexible fluid line (41).

34. Fluid feed apparatus according to any one of clauses 30 to 33, wherein the insertion component (39, 40) is rod-shaped and the guide channel (47) extends from an end face (48) of the insertion component (39) to a lateral surface (45) of the insertion component (39).

35. Fluid feed apparatus according to clause 34, wherein the guide channels (41) merge into openings (46) at the lateral surface (45) of the insertion component (39), the openings preferably being arranged next to one another in the longitudinal direction (Y) of the insertion component (39) and being in particular arranged at equal distances (A) from one another in the longitudinal direction (Y) of the insertion component (39).

36. Fluid feed apparatus according to clause 34 or 35, wherein the rod-shaped insertion component (39) has a cylindrical form and preferably has a diameter (D) of between 5 mm and 10 mm.

37. Fluid feed apparatus according to any one of clauses 30 to 36, wherein the at least one guide channel (47) has a diameter (d) of between 1 mm and 4 mm.

38. Fluid feed apparatus according to any one of clauses 30 to 37, wherein the at least one fluid line (41) has an external diameter (F) of 1 mm or less.

39. Fluid feed apparatus according to any one of clauses 30 to 38, further comprising: a fluid provision device (43) for feeding the fluid (28) to the at least one flexible fluid line (41).

40. Fluid feed apparatus according to any one of clauses 30 to 39, further comprising: at least one tracking device (44) for automated tracking by the at least one flexible fluid line (41) of a movement of the ablation front (30a, 30b) in the material of the workpiece (25).

41. Method for feeding a fluid (28) with a fluid feed apparatus (38) according to any one of clauses 30 to 40 to at least one ablation front (30a, 30b) when removing material from a workpiece through multi-photon laser ablation, in particular from a preferably monolithic substrate (25) for an EUV mirror (M4), comprising:
inserting the insertion component (39, 40) into a cavity (33, 35) of the workpiece (25) and feeding the fluid (28) to the at least one ablation front (30a, 30b) through the at least one flexible fluid line (41), which is guided in the at least one guide channel (47) of the insertion component (39, 40).

42. Method according to clause 41, wherein the cavity (33, 35) is filled with a fluid (28) prior to the insertion of the insertion component (39, 40) and a plurality of channel sections (37) adjacent to the cavity (33, 35) are formed by multi-photon laser ablation starting with the cavity (33, 35) that is filled with the fluid (28).

43. Method according to clause 42, wherein a plurality of ablation fronts (30a, 30b) are generated starting from the channel sections (37) following the insertion of the insertion component (39, 40) into the cavity (33, 35) and are moved in the material of the workpiece (25) in order to form a plurality of channels (31, 34, 35), with the plurality of the flexible fluid lines (41) tracking the movement of the ablation fronts (30a, 30b) in the material of the workpiece (25).

1.-30. (canceled)

31. Mirror, comprising:
a substrate, and
a radiation-reflective coating on the substrate,
wherein the substrate comprises at least one channel formed from pulsed laser radiation radiated into the substrate and configured as a flow-passage for a fluid,
wherein the substrate consists at least essentially of a material transparent to the pulsed laser radiation focused into a focal region of the substrate from a radiation entrance side,
wherein the channel is produced by moving a removal front within the substrate, wherein the removal front, for areal removal of material of the substrate, is formed by moving the focal region along a movement pattern, and
wherein the removal front is aligned non-perpendicularly to an incoming direction of the pulsed laser radiation at the radiation entrance side of the substrate at least intermittently during the production of the channel.

32. Mirror, comprising:
a substrate comprising at least one channel configured as a flow-passage for a fluid,
wherein the channel is formed through material-removing processing with pulsed laser radiation,
wherein the channel has a curved form,
and wherein the channel has a diameter of between 1 mm and 20 mm and/or a length of at least 10 cm.

33. Mirror according to claim 32, wherein the substrate is monolithic.

34. Mirror according to claim 32, wherein the channel has a first section and a second section adjacent to the first section, and wherein longitudinal directions of the first section and the second section are aligned with respect to one another at an angle of between 70° and 100°.

35. Mirror according to claim 34, wherein the first section and the second section merge into one another in a rounded-off section.

36. Mirror, comprising:
a substrate,
a radiation-reflective coating applied to a surface of the substrate, and
at least one hollow structure extending in the substrate and configured as a flow-passage for a fluid,
wherein the hollow structure has a first section and a second section neighboring the first section, which are aligned with respect to one another at an angle of between 60° and 120°, and
wherein the hollow structure has a rounded-off section, at which the first section and the second section merge into one another.

37. Mirror according to claim 36, wherein an R/D ratio between a radius of curvature R of the rounded-off section and a diameter D of the rounded-off section is between 2 and 6.

38. Mirror according to claim 36, wherein a diameter D of the rounded-off section is between 2 mm and 20 mm.

39. Mirror according to claim 36, wherein the hollow structure comprises a plurality of temperature control channels which extend below the surface to which the reflective coating is applied, and wherein the hollow structure comprises a fluid distributor connected to the temperature control channels via distributor channels and a fluid collector connected to the temperature control channels via collector channels.

40. Mirror according to claim 39, wherein the first section forms a distribution end section of the temperature control channel adjacent to one of the distributor channels and the second section forms a distributor channel section adjacent to the distribution end section and/or wherein the first section forms a collection end section of the temperature control channel adjacent to one of the collector channels and wherein the second section forms a collector channel section adjacent to the collection end section.

41. Mirror according to claim 39, wherein the fluid distributor forms an inlet channel, from which the distributor channels branch off, and/or wherein the fluid collector forms an outlet channel, from which the collector channels branch off.

42. Mirror according to claim 41, wherein the first section forms a merging section of the distributor channel neighboring the inlet channel and wherein the second section forms a branching section of the inlet channel neighboring the merging section, and/or wherein the first section forms a merging section of the collector channel neighboring the outlet channel and wherein the second section forms a branching section of the outlet channel neighboring the merging section of the collector channel.

43. Mirror according to claim 42, wherein the angle between the branching section of the inlet channel and the merging section of the distributor channel is greater than 90°, and/or wherein the angle between the branching section of the outlet channel and the merging section of the collector channel is greater than 90°.

44. Mirror according to claim 36, wherein the substrate consists at least essentially of a material selected from the group consisting of: fused silica and glass ceramic.

45. Mirror according to claim 36, wherein the substrate consists at least essentially of a material that has a zero-crossing temperature which is between 0° C. and 100° C.

46. Mirror according to claim 36, wherein the substrate consists at least essentially of a material that has a spatial variation of a zero-crossing temperature which is less than 3 K.

47. Mirror according to claim 36, wherein the hollow structure has a seam region.

48. Mirror according to claim 47, wherein the hollow structure has at least one of: an edge contour of a removal front, at least one bulge, a lateral offset and a structural modification other than the edge contour, the bulge or the offset in the seam region.

49. Mirror, comprising:
a substrate which comprises a channel, the channel having a seam region.

50. Mirror according to claim 49, wherein the channel has at least one of: an edge contour of a removal front, at least one bulge, a lateral offset and a structural modification other than the edge contour, the bulge or the offset in the seam region.

51. Extreme ultraviolet (EUV) lithography system comprising: at least one EUV mirror according to claim 36 and a temperature control device configured as a hollow structure forming a flow-passage for a temperature control fluid.

52.-72. (canceled)

73. Mirror according to claim 36, wherein the substrate is a monolithic substrate, and the reflective coating is configured to reflect extreme ultraviolet (EUV) radiation.

74. Mirror according to claim 39, wherein the temperature control channels are configured as cooling channels.

75. Mirror according to claim 49, wherein the substrate is a monolithic substrate, and wherein the channel is curved and is configured as a flow-passage for a fluid.

76. Mirror according to claim 44, wherein the substrate consists at least essentially of titanium-doped fused silica.
